(19) United States
(12) Patent Application Publication
(10) Pub. No.: US 2026/0100206 A1
(43) Pub. Date: Apr. 9, 2026

(54) SEMICONDUCTOR MEMORY DEVICES WITH EMBEDDED POWER STRUCTURE AND METHODS OF MANUFACTURING THEREOF

(71) Applicant: Taiwan Semiconductor Manufacturing Company, Ltd., Hsinchu (TW)

(72) Inventors: Ting-Yun Wu, Hsinchu City (TW); Lu Yang, Hsinchu City (TW); Szuya Liao, Hsinchu City (TW); Jui-Lin Chen, Hsinchu City (TW); Kian-Long Lim, Hsinchu City (TW); Ping-Wei Wang, Hsinchu City (TW); Yung-Ting Chang, Hsinchu City (TW)

(73) Assignee: Taiwan Semiconductor Manufacturing Company, Ltd., Hsinchu (TW)

(21) Appl. No.: 19/049,338

(22) Filed: Feb. 10, 2025

Related U.S. Application Data
(60) Provisional application No. 63/704,287, filed on Oct. 7, 2024.

(51) Int. Cl. G11C 5/06; H10B 10/00; H10D 30/00; H10D 30/01; H10D 30/43; H10D 62/10; H10D 64/23; H10D 84/01; H10D 84/85

(52) U.S. Cl. CPC G11C 5/063; H10B 10/125; H10D 30/014; H10D 30/0191; H10D 30/43; H10D 30/502; H10D 62/121; H10D 64/251; H10D 84/0186; H10D 84/851

(57) ABSTRACT

A device includes a substrate having a first side and a second side; a first transistor and a second transistor formed in a first level on the first side; a third transistor, a fourth transistor, a fifth transistor, and a sixth transistor formed in a second level on the first side; a first interconnect structure, a second interconnect structure, a third interconnect structure, and a fourth interconnect structure formed on the second side, the first and second interconnect structures each configured to carry a supply voltage, and the third and fourth interconnect structures each configured to carry a ground voltage; and a power structure vertically extending through the first and second levels, and configured to electrically couple a source/drain terminal of the third transistor and a source/drain terminal of the fourth transistor to the third interconnect structure and the fourth interconnect structure, respectively.

### CROSS-REFERENCE TO RELATED APPLICATION

This application claims priority to and the benefit of U.S. Provisional Application No. 63/704,287, filed Oct. 7, 2024, entitled “INTEGRATED CIRCUIT AND METHOD OF MANUFACTURING,” which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. For example, various advanced transistor structures such as, complementary field-effect transistors (CFETs), have been proposed in accordance with such a scaling trend.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example circuit diagram of a memory cell, in accordance with some embodiments.

FIGS. 2-3 illustrate layouts that are collectively configured to form the memory cell of FIG. 1 in a CFET structure with an embedded power structure, in accordance with some embodiments.

FIGS. 4-5 respectively illustrate perspective views of a portion of the memory cell formed based on the layouts of FIGS. 2-3, in accordance with some embodiments.

FIGS. 6-7 illustrate layouts that are collectively configured to form the memory cell of FIG. 1 in a CFET structure with an embedded power structure, in accordance with some embodiments.

FIGS. 8-9 respectively illustrate perspective views of a portion of the memory cell formed based on the layouts of FIGS. 6-7, in accordance with some embodiments.

FIGS. 10-11 respectively illustrate cross-sectional views of the memory cell shown in FIGS. 4-5, in accordance with some embodiments.

FIGS. 12-13 respectively illustrate cross-sectional views of the memory cell shown in FIGS. 8-9, in accordance with some embodiments.

FIGS. 14-15 respectively illustrate top views of the memory cell shown in FIGS. 4-5 or FIGS. 8-9, in accordance with some embodiments.

FIGS. 16-17 respectively illustrate top/bottom views of the memory cell shown in FIGS. 4-5 or FIGS. 8-9, in accordance with some embodiments.

FIG. 18 illustrates an example flow chart of a method for forming a semiconductor device including a memory cell configured with a CFET structure, in accordance with some embodiments.

FIGS. 19-28 illustrate cross-sectional views of an example semiconductor device during various fabrication stages, made by the method of FIG. 18, in accordance with some embodiments.

FIG. 29 illustrates an example flow chart of a method for forming a semiconductor device including a memory cell configured with a CFET structure, in accordance with some embodiments.

FIGS. 30-41 illustrate cross-sectional views of an example semiconductor device during various fabrication stages, made by the method of FIG. 35, in accordance with some embodiments.

FIGS. 42-43 illustrate layouts that are collectively configured to form a pair of the memory cells of FIG. 1 in a CFET structure with an embedded power structure, in accordance with some embodiments.

FIGS. 44-45 respectively illustrate layouts for forming frontside and backside metal tracks for the memory cells formed based on the layouts of FIGS. 42-43, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary field-effect transistors (CFETs) are one type of gate-all-around (GAA) field-effect transistors. In general, a GAA FET includes a plural number of nanostructures, such as nanosheets or nanowires, vertically stacked on top of one another. P-type and n-type GAA FETs are formed on the same horizontal plane over a substrate and are separated by isolation structures. In contrast, a CFET is commonly fabricated by vertically stacking a p-type GAA FET and an n-type GAA FET on top of each other. This stacking configuration of n-type and p-type transistors in a single structure eliminates the need for an n-to-p separation, reduces the active area footprint, and increases the transistor density within a chip. This stacking concept is not limited to GAA FETs; for example, CFETs can be formed with FinFET devices or with a combination of GAA FETs and FinFETs.

It has been proposed to form static random access memory (SRAM) cells based on the CFET structures. For example, to form an SRAM cell with six transistors (6T) generally referred to as a 6T SRAM cell, a first level including a first pull-up transistor and a second pull-up transistor is first formed on the frontside of a substrate, followed by a second level including a first pull-down transistor, a second pull-down transistor, a first pass-gate transistor, and a second pass-gate transistor formed over the first level (on the frontside of the substrate). Generally, the pull-up transistors are commonly formed with a p-type conductivity and the pull-down and pass-gate transistors are commonly formed with an n-type conductivity.

With the n-type pull-down transistors formed over the p-type transistors, a tap cell or filler cell is commonly needed for forming a via structure extending from the second level through the substrate to a backside of the substrate, when adopting a backside power grid (BPG)/buried power rail (BPR) configuration. In the BPG/BPR configuration, a number of interconnect structures, configured to carry a reference or ground voltage (e.g., VSS), are formed on the backside of the substrate. The tap cell (or the via structure included therein) is configured to electrically couple the pull-down transistors at the second level to the interconnect structures carrying the ground voltage. Such additional tap cells disadvantageously take up a relatively large amount of area. For example, a plural number of these tap cells are typically formed around or away from an array including the memory cells. Stated another way, additional areas are needed to form those tap cells. Thus, the existing CFET structures for forming memory cells have not been entirely satisfactory in certain aspects.

The present disclosure provides various embodiments of a semiconductor device (e.g., a memory cell) formed in a CFET structure that has first and second frontside levels of a substrate for forming respectively different conductive types of transistors, with a power structure embedded within or along a boundary of the memory cell. According to some embodiments, the memory device may include at least one SRAM cell with plural (e.g., 6) transistors. The SRAM cell, as disclosed herein, can include first and second p-type pull-up transistors formed at the first frontside level, and first and second n-type pass-gate transistors and first and second n-type pull-down transistors formed at the second frontside level. With the power structure embedded within or along the (e.g., cell) boundary of the SRAM cell, no additional tap cell configured for carrying the ground voltage is needed. For example, at the first level, the first and second pull-up transistors may be disposed around one pair of diagonal corners of the boundary, respectively. Further, at the first level, a first dummy transistor may be disposed next to the first pull-up transistor along a first lateral direction, and a second dummy transistor may be disposed next to the second pull-up transistor along the first lateral direction (i.e., the first and second dummy transistors arranged around the other diagonal corners of the boundary, respectively). At the second level, the first pull-down transistor may be vertically aligned with the first pull-up transistor, the second pull-down transistor may be vertically aligned with the second pull-up transistor, the first pass-gate transistor may be vertically aligned with the first dummy transistor, and the second pass-gate transistor may be vertically aligned with the second dummy transistor.

The power structure, which can be formed as one or more vertical structures extending from the first level to the second level, can be formed along a middle line of the boundary (extending along the first lateral direction). For instance, the power structure can be interposed between the first pull-up transistor and the second dummy transistor along a second lateral direction perpendicular to the first lateral direction, interposed between the second pull-up transistor and the first dummy transistor along the second lateral direction, interposed between the first pass-gate transistor and the second pull-down transistor along the second lateral direction, and interposed between the first pull-down transistor and the second pass-gate transistor along the second lateral direction. Through the power structure, the first and second pull-down transistors at the second level can each be electrically coupled to interconnect structures formed on a backside level of the substrate that are configured to carry the ground voltage. As such, the disclosed SRAM cell does not require additional tap cell disposed around to provide the ground voltage.

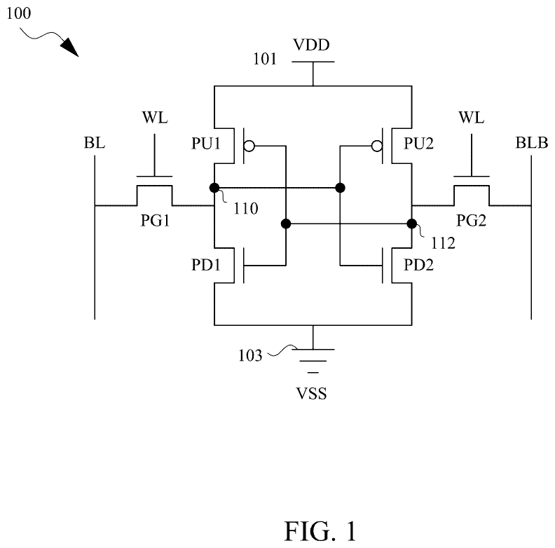

FIG. 1 illustrates an example circuit diagram of a memory cell 100, in accordance with some embodiments. As shown, the memory cell 100 includes six transistors that operatively form a 6T SRAM cell. In various embodiments, the six transistors can be physically formed with a CFET structure which will be discussed below. The memory cell 100 includes six transistors: a first pull-up transistor PU1, a second pull-up transistor PU2, a first pull-down transistor PD1, a second pull-down transistor PD2, a first pass-gate transistor PG1, and a second pass-gate transistor PG2.

The transistors PU1 and PD1 are formed as a first inverter and the transistors PU2 and PD2 are formed as a second inverter, wherein the first and second inverters are cross coupled to each other. Specifically, the first and second inverters are each coupled between first voltage reference 101 and second voltage reference 103. In some embodiments, the first voltage reference 101 is a supply voltage applied to the memory cell 100, sometimes referred to as “VDD,” and the second voltage reference 103 is a ground voltage, sometimes referred to as “VSS.” The first inverter (formed by the transistors PU1 and PD1) is coupled to the transistor PG1, and the second inverter (formed by the transistors PU2 and PD2) is coupled to the transistor PG2. In addition to being coupled to the first and second inverters, the transistors PG1 and PG2 are each coupled to a word line (WL) and are coupled to a bit line (BL) and a bit line bar (BLB), respectively.

In some embodiments, the transistors PU1 and PU2 each include a p-type metal-oxide-semiconductor (PMOS) transistor, and the transistors PD1, PD2, PG1, and PG2 each include an n-type metal-oxide-semiconductor (NMOS) transistor. Although the illustrated embodiment of FIG. 1 shows that the transistors of the memory cell 100 are either NMOS or PMOS transistors, any of a variety of transistors or devices that are suitable for use in a memory device may be implemented as at least one of the transistors of the memory cell 100 such as, for example, a bipolar junction transistor (BJT), a high-electron-mobility transistor (HEMT), etc. Further, as will be discussed below, the p-type transistors, PU1 and PU2, are each formed as a GAA FET at a first level disposed on the frontside of a substrate, and the n-type transistors, PG1, PG2, PD1, and PD2, are each formed as a GAA FET at a second level over the first level.

The transistors PG1 and PG2 each have a gate terminal coupled to the WL. The gate terminals of the transistors PG1 and PG2 are configured to receive a pulse signal, through the WL, to allow or block an access (e.g., a read operation, a write operation) of the memory cell 100 accordingly. The transistors PD1 and PU1 are coupled between VDD and VSS, and coupled to each other at internal node 110. For example, the transistor PU1 has a first source/drain terminal connected to VDD and the transistor PD1 has a first source/drain terminal connected to VSS, with the transistors PU1 and PD1 having their second source/drain terminals connected to each other at the internal node 110. The transistor PG1 has a first source/drain terminal connected to the BL and a second source/drain terminal connected to the internal node 110, which is further coupled to gate terminals of the transistors PU2 and PD2. Similarly, the transistors PD2 and PU2 are coupled between VDD and VSS, and coupled to each other at internal node 112. For example, the transistor PU2 has a first source/drain terminal connected to VDD and the transistor PD2 has a first source/drain terminal connected to VSS, with the transistors PU2 and PD2 having their second source/drain terminals connected to each other at the internal node 112. The transistor PG2 has a first source/drain terminal connected to the BLB and a second source/drain terminal connected to the internal node 112, which is further coupled to gate terminals of the transistors PU1 and PD1.

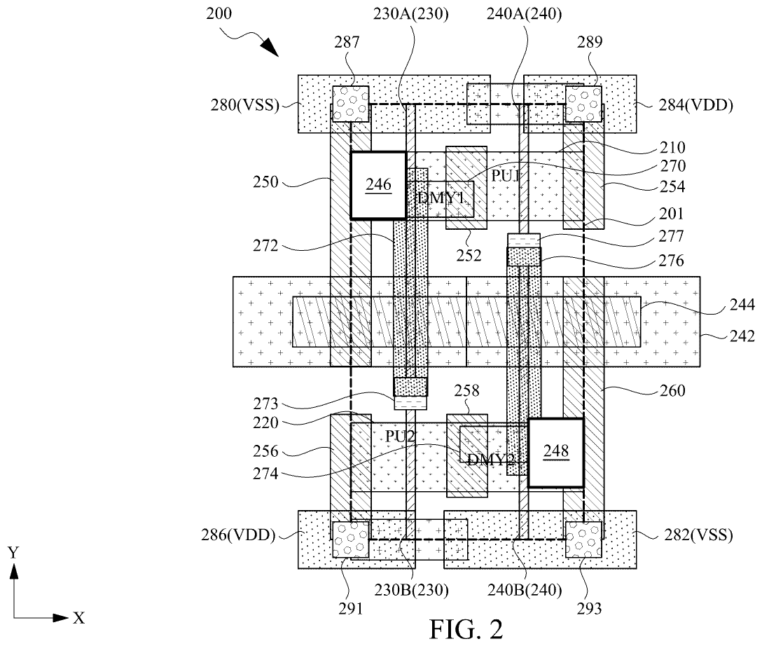

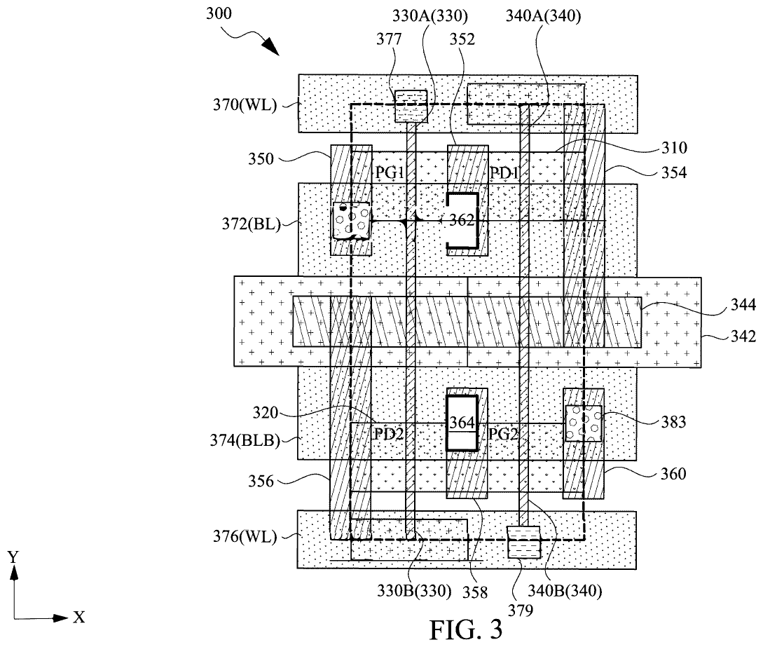

FIG. 2 and FIG. 3 respectively illustrate layouts 200 and 300, which can be collectively utilized to form the memory cell 100 (FIG. 1) configured in a CFET structure with an embedded power structure, in accordance with some embodiments. The CFET structure can include a number of first transistors disposed at a first level on the frontside of a substrate, and a number of second transistors disposed at a second, upper level on the frontside of the substrate. In some embodiments, each of these first and second transistors is configured as a GAA FET, with the first transistors and the second transistors having opposite conductive types. In some other embodiments, each of the first and second transistors can be formed as other type of transistor structures, while remaining within the scope of the present disclosure.

As depicted in FIGS. 2-3, each of the layouts 200 and 300 can include a cell boundary 201 defining a physical area of the memory cell 100. The embedded power structure can be formed as a one-piece wall structure vertically extending from the first level to the second level. Further, when viewed from the top, such an embedded wall structure can be disposed within the cell boundary 201 of the memory cell 100. For example, the wall structure may laterally extend along a middle line of the cell boundary 201, with the transistors disposed on the opposite sides of the middle line, respectively. The middle line can cross the cell boundary in a first lateral direction, with edges of the cell boundary that extend along a second lateral direction perpendicular to the first lateral direction disposed on lengthwise ends of the middle line, respectively.

Generally, each of the layouts 200 and 300 can include a number of patterns configured for forming respective structures, and thus, such patterns of the disclosed layout are herein referred to as the structures to be formed, respectively, in the following discussion. For example, the layout 200 includes patterns configured to form structures of the first transistors at the first level on the frontside; and the layout 300 includes patterns configured to form structures of the second transistors at the second level on the frontside. Further, the layout 200 includes patterns configured to form contact/via/interconnect structures disposed on a backside of the substrate (e.g., at a first level on the backside); and the layout 300 includes patterns configured to form via/interconnect structures at a third level on the frontside (e.g., over the second level). It should be understood that each of the layouts 200 and 300 has been simplified for illustrative purposes, and thus, can include any of various other patterns while remaining within the scope of the present disclosure.

Referring first to FIG. 2, the layout 200 can include patterns for forming active regions 210 and 220 and gate structures 230 and 240, respectively. The active regions 210 and 220 may extend in the X-direction (e.g., a first lateral direction); and the gate structures 230 and 240 may extend in the Y-direction (e.g., a second lateral direction). Each of the active regions 210 and 220 may be formed as a fin structure or a stack structure extending along the X-direction, and each of the gate structures 230 and 240 may be formed to extend in the Y-direction to traverse the active regions 210 and 220.

The layout 200 can further include a number of cut patterns (e.g., 242), each of which extends along the X-direction traversing one or more of the gate structures 230-240. As shown, the cut pattern 242, extending along the X-direction to traverse both the gate structures 230-240, can be configured to define the footprint of a dielectric structure (hereinafter “dielectric structure 242”). The dielectric structure 242 can be formed along the middle line of the boundary 201, so as to divide each of the gate structures 230-240 into separate gate sections, e.g., gate sections 230A and 230B and gate sections 240A and 240B. A power structure, implemented as a one-piece wall structure 244 vertically extending, can be formed to extend through the dielectric structure 242.

Referring next to FIG. 3, the layout 300 can include patterns for forming active regions 310 and 320 and gate structures 330 and 340, respectively. The active regions 310 and 320 may extend in the X-direction; and the gate structures 330 and 340 may extend in the Y-direction. Each of the active regions 310 and 320 may be formed as a fin structure or a stack structure extending along the X-direction, and each of the gate structures 330 and 340 may be formed to extend in the Y-direction to traverse the active regions 310 and 320.

The layout 300 can further include a number of cut patterns (e.g., 342), each of which extends along the X-direction traversing one or more of the gate structures 330-340. As shown, the cut pattern 342, extending along the X-direction to traverse both the gate structures 330-340, can be configured to define the footprint of a dielectric structure (hereinafter “dielectric structure 342”). The dielectric structure 342 can be formed along the middle line of the boundary 201, so as to divide each of the gate structures 330-340 into separate gate sections, e.g., gate sections 330A and 330B and gate sections 340A and 340B. A power structure, implemented as a one-piece wall structure 344 vertically extending, can be formed to extend through the dielectric structure 342.

In some embodiments, the active regions 210 and 310 are vertically aligned with each other, the active regions 220 and 320 are vertically aligned with each other, the gate structures 230 and 330 are vertically aligned with each other, and the gate structures 240 and 340 are vertically aligned with each other. The active regions 210 and 310 may be physically formed as a single structure (sometimes referred to as “active region 210/310”), the active regions 220 and 320 may be physically formed as a single structure (sometimes referred to as “active region 220/320”), the gate structures 230 and 330 may be physically formed as a single structure (sometimes referred to as “gate structure 230/330”), and the gate structures 240 and 340 may be physically formed as a single structure (sometimes referred to as “gate structure 240/340”).

Further, in some embodiments, the dielectric structures 242 and 342 are vertically aligned with each other, and the wall structures 244 and 344, respectively disposed in the dielectric structures 242 and 342, are vertically aligned with each other. The dielectric structures 242 and 342 may be physically formed as a single structure (sometimes referred to as “dielectric structure 242/342”), and the wall structures 244 and 344 may be physically formed as a single structure (sometimes referred to as “wall structure 244/344”). As such, the dielectric structure 242/342 and the wall structure 244/344 can vertically extend from the first level to the second level, such that the dielectric structure 242/342 can cut the gate structure 230 into the gate sections 230A and gate sections 230B, the gate structure 330 into the gate sections 330A and gate sections 330B, the gate structure 240 into the gate sections 240A and gate sections 240B, and the gate structure 340 into the gate sections 340A and gate sections 340B. In some embodiments, the gate sections 230A and 330A can be coupled to each other (sometimes referred to as “gate section 230A/330A”), the gate sections 230B and 330B can be coupled to each other (sometimes referred to as “gate section 230B/330B”), the gate sections 240A and 340A can be coupled to each other (sometimes referred to as “gate section 240A/340A”), and the gate sections 240B and 340B can be coupled to each other (sometimes referred to as “gate section 240B/340B”).

For example, the active region 210/310 and active region 220/320 can each be first formed as a stack structure protruding from the frontside surface of a substrate. The stack may include a number of first semiconductor nanostructures (e.g., first nanosheets) extending along the X-direction and vertically separated from each other, and a number of second semiconductor nanostructures (e.g., second nanosheets) extending along the X-direction and vertically separated from each other. The first nanosheets are positioned at the first level, and the second nanosheets are positioned at the second level. According to some embodiments of the present disclosure, the first nanosheets, formed based on a lower portion of the active region 210/310 or a lower portion of the active region 220/320, can partially form the first transistors at the first level; and the second nanosheets, formed based on an upper portion of the active region 210/310 or an upper portion of the active region 220/320, can partially form the second transistors at the second level. Further, the first nanosheets and the second nanosheets can be vertically aligned with but separated from each other, with at least one dielectric layer interposed therebetween.

Next, respective portions of the first and second nanosheets in each of the stacks that are overlaid by the gate structure 230/330 and the gate structure 240/340, which are initially formed as a number of dummy (e.g., polysilicon) gate structures, respectively, may remain. Other portions of the first nanosheets are replaced with a number of first epitaxial structures, and other portions of the second nanosheets are replaced with a number of second epitaxial structures. According to some embodiments of the present disclosure, the first epitaxial structures (at the first level) may be formed with a p-type conductivity, and the second epitaxial structures (at the second level) may be formed with an n-type conductivity. The first epitaxial structures can operatively form respective source/drain terminals of the first transistors at the first level, and the second epitaxial structures can operatively form respective source/drain terminals of the second transistors at the second level.

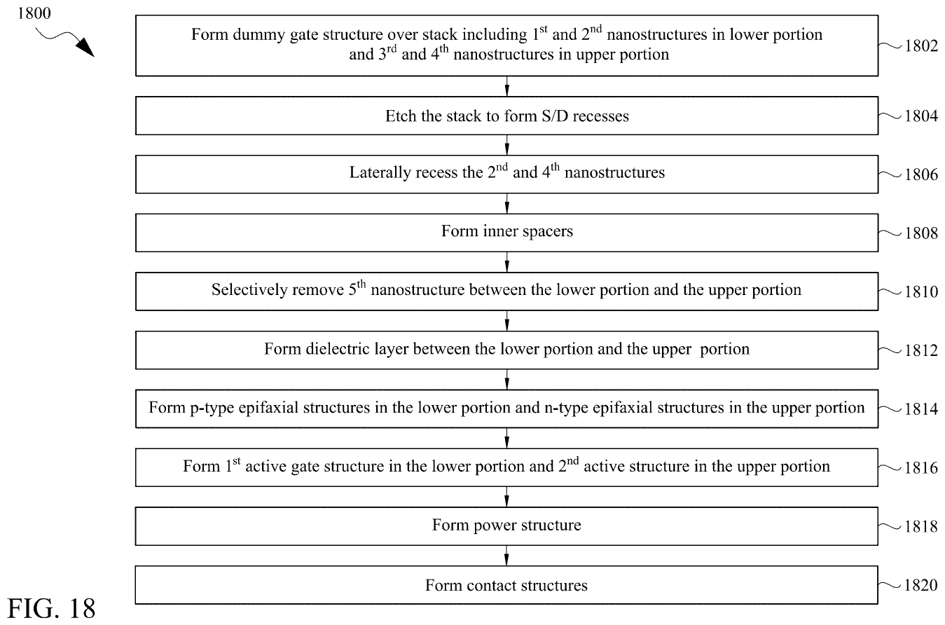

Next, each of the dummy gate structures 230/330 and 240/340 can be replaced by a corresponding active (e.g., metal) gate structure to form the first and second transistors. According to some embodiments of the present disclosure, each of the active gate structures can include a lower portion and an upper portion corresponding to the first level and the second level, respectively. For example, the lower portion of the active gate structure (e.g., corresponding to the gate section 230A, 230B, 240A, or 240B) may include one or more first work function metals configured for forming a gate terminal of one of the first transistors with the p-type conductivity, and the upper portion of the active gate structure (e.g., corresponding to the gate section 330A, 330B, 340A, or 340B) may include one or more second work function metals configured for forming a gate terminal of one of the second transistors with the n-type conductivity. Details of a series of manufacturing processes to form a semiconductor device that includes the structures of first transistors at a first level and second transistors at a second level will be described with respect to FIGS. 18-41.

As a brief overview, the transistors PU1 and PU2 of the memory cell 100 (FIG. 1) can be formed at the first level based on the layout 200 (as indicated in FIG. 2), and the transistors PG1, PG2, PD1, and PD2 of the memory cell 100 (FIG. 1) can be formed at the second level based on the layout 300 (as indicated in FIG. 3). In some embodiments, the transistors PU1 and PU2 at the first level can be formed with the p-type conductivity, and the transistors PG1, PG2, PD1, and PD2 at the second level can be formed with the n-type conductivity. Further, a first dummy transistor DMY1 and a second dummy transistor DMY2, each of which has one of its first epitaxial structures (e.g., source/drain terminals) replaced with an isolation structure, can be formed at the first level.

For example, in FIG. 2, the transistor PU1 can include its channel, gate terminal, and source/drain terminals formed by a subset of the first nanosheets in the active region 210, the gate section 240A, and a subset of the first epitaxial structures formed from the active region 210 and disposed on opposite sides of the gate section 240A, respectively. The transistor PU2 can include its channel, gate terminal, and source/drain terminals formed by a subset of the first nanosheets in the active region 220, the gate section 230B, and a subset of the first epitaxial structures formed from the active region 220 and disposed on opposite sides of the gate section 230B, respectively. The transistor DMY1 can include its channel, gate terminal, and source/drain terminals formed by a subset of the first nanosheets in the active region 210, the gate section 230A, and a subset of the first epitaxial structures formed from the active region 210 and disposed on opposite sides of the gate section 230A, respectively. In some embodiments, one of the source/drain terminals (e.g., the first epitaxial structure disposed opposite the gate section 230A from the gate section 240A) of the transistor DMY1 can be replaced with isolation structure 246. The transistor DMY2 can include its channel, gate terminal, and source/drain terminals formed by a subset of the first nanosheets in the active region 220, the gate section 240B, and a subset of the first epitaxial structures formed from the active region 220 and disposed on opposite sides of the gate section 240B, respectively. In some embodiments, one of the source/drain terminals (e.g., the first epitaxial structure disposed opposite the gate section 240B from the gate section 230B) of the transistor DMY2 can be replaced with isolation structure 248.

In another example, in FIG. 3, the transistor PD1 can include its channel, gate terminal, and source/drain terminals formed by a subset of the second nanosheets in the active region 310, the gate section 340A, and a subset of the second epitaxial structures formed from the active region 310 and disposed on opposite sides of the gate section 340A, respectively. The transistor PG1 can include its channel, gate terminal, and source/drain terminals formed by a subset of the second nanosheets in the active region 310, the gate section 330A, and a subset of the second epitaxial structures formed from the active region 310 and disposed on opposite sides of the gate section 330A, respectively. The transistor PD2 can include its channel, gate terminal, and source/drain terminals formed by a subset of the second nanosheets in the active region 320, the gate section 330B, and a subset of the second epitaxial structures formed from the active region 320 and disposed on opposite sides of the gate section 330B, respectively. The transistor PG2 can include its channel, gate terminal, and source/drain terminals formed by a subset of the second nanosheets in the active region 320, the gate section 340B, and a subset of the second epitaxial structures formed from the active region 320 and disposed on opposite sides of the gate section 340B, respectively.

Referring again to FIG. 2, the layout 200 can further include patterns for forming source/drain contact structures 250, 252, 254, 256, 258, and 260, respectively. Such source/drain contact structures 250 to 260 are each sometimes referred to as MD. In general, each of these MDs 250 to 260 is configured to electrically connect the source/drain terminal of a corresponding transistor to an upper or lower interconnect structure. However, some of the MDs 250 to 260 (e.g., 250, 260) may each be physically coupled to a corresponding isolation structure that replaces an epitaxial structure (e.g., 246, 248), according to some embodiments of the present disclosure. Each of the MDs 250 to 260 can be physically coupled to or wrap around the corresponding epitaxial structure or isolation structure. In some embodiments, each of the MDs 250 to 260 can laterally extend along the same direction as the gate structures 230-240, e.g., the Y-direction.

For example, in FIG. 2, the MD 250 is coupled to a bottom surface of the isolation structure 246; the MD 260 is coupled to a bottom surface of the isolation structure 248; the MD 254 is coupled to a bottom surface of one of the source/drain terminals of the transistor PU1, while the MD 252 is coupled to a bottom surface of the other source/drain terminal of the transistor PU1; and the MD 256 is coupled to a bottom surface of one of the source/drain terminals of the transistor PU2, while the MD 258 is coupled to a bottom surface of the other source/drain terminal of the transistor PU2.

The layout 200 can further include patterns for forming internal contact structures 270 and 274, respectively; patterns for forming interconnect structures 272, 276, 280, 282, 284, and 286 in the first level on the backside, respectively; and patterns for forming via structures 273, 277, 287, 289, 291, and 293, respectively. In some embodiments, each of the internal contact structures 270 and 274 can be formed below and coupled to an MD. Further, the internal contact structures 270 and 274 can each extend along the X-direction to connect to an interconnect structure formed underneath (e.g., a BM0 track), which will be discussed below. In some embodiments, each of the internal contact structures 270 and 274 may be vertically disposed between an MD and a BM0 track. For example, the internal contact structures 270 and 274 may be vertically interposed between a backside surface of the substrate and the BM0 layer. Each of the via structures 273 and 277 is typically formed below a gate structure or downwardly extends from the gate structure (sometimes referred to as BVG). The BVGs 273 and 277 are each coupled to the corresponding gate structure. Each of the via structures 287 to 293 is typically formed below an MD or downwardly extends from the MD (sometimes referred to as BVD). The BVDs 287 to 293 are each couped to the corresponding MD.

The first level, disposed on the backside, may sometimes be referred to as a bottommost one of plural backside metallization layers, e.g., BM0 layer, and the interconnect structures 272, 276, 280, 282, 284, and 286 disposed therein are each sometimes referred to as a BM0 track. The backside metallization layer typically includes one or more dielectric materials (e.g., silicon, oxide, a low-k dielectric material, or the like) embedding the corresponding metal tracks formed of, e.g., copper. These BM0 tracks 272, 276, 280, 282, 284, and 286 (including the internal contact structures 270 and 274) can extend along the X-direction or the Y-direction, as shown in FIG. 2.

In some embodiments, the BM0 tracks 272 and 276 can each be coupled to a corresponding one of the overlaying gate structure (or gate section) in the first level on the frontside through a BVG, and the BM0 tracks 280 to 286 can each be coupled to a corresponding one of the overlaying MDs in the first level on the frontside through a BVD. For example, the BM0 track 280 is coupled to the MD 250 through the BVD 287; the BM0 track 282 is coupled to the MD 260 through the BVD 293; the BM0 track 284 is coupled to the MD 254 through the BVD 289; and the BM0 track 286 is coupled to the MD 256 through the BVD 291. The BM0 tracks 280 and 282 can each operatively serve a part of a power rail carrying the ground voltage VSS, and the BM0 tracks 284 and 286 can each operatively serve as another power rail carrying the supply voltage VDD.

In some embodiments, these power rails (e.g., 280 to 286) may be disposed at the corners of the boundary 201, respectively, with the BM0 tracks (VSS) 280 and 282 disposed diagonally opposite to each other and the BM0 tracks (VDD) 284 and 286 disposed diagonally opposite to each other. With the MDs 250 and 260 disposed along the Y-direction, the wall structure 244/344, disposed along the middle line of the boundary 201, can be coupled to the BM0 tracks (VSS) 280 and 282 that extend along the X-direction. For example, the MDs 250 and 260 can be coupled to (or overlapped with when viewed from the top/bottom) the wall structure 244/344, as shown in FIG. 2. Along each of its lengthwise direction (e.g., the Y-direction), the MDs 250 and 260 can couple the wall structure 244/344 to the BM0 tracks (VSS) 280 and 282, respectively.

Further, the internal contact structure 270 can be coupled to the BM0 track 272 that is coupled to the gate terminal of the transistor PU2, and the internal contact structure 274 can be coupled to the BM0 track 276 that is coupled to the gate terminal of the transistor PU1. As the internal contact structure 270 extends in the X-direction and the BM0 track 272 extends in the Y-direction, the internal contact structure 270 and the BM0 track 272 can collectively form an L-shaped profile, when viewed from the top or bottom. Similarly, the internal contact structure 274 and the BM0 track 276 can collectively form another L-shaped profile, when viewed from the top or bottom. In some other embodiments, the internal contact structure 270 and the BM0 track 272 can be formed in the same level, e.g., an intermediate level vertically between the backside surface of the substrate and the BM0 layer. Similarly, the internal contact structure 274 and the BM0 track 276 can be formed in the same intermediate level.

As such, connection between one of the source/drain terminals of the transistor PU1 and the gate terminal of the transistor PU2 (or the internal node 110 of FIG. 1) can be operatively formed at least by the MD 252 (connected to that source/drain terminal of the transistor PU1), the internal contact structure 270, the BM0 track 272, and the BVG 273 (connected to the gate terminal of the transistor PU2); and connection between one of the source/drain terminals of the transistor PU2 and the gate terminal of the transistor PU1 (or the internal node 112 of FIG. 1) can be operatively formed at least by the MD 258 (connected to that source/drain terminal of the transistor PU1), the internal contact structure 274, the BM0 track 276, and the BVG 277 (connected to the gate terminal of the transistor PU1).

Referring again to FIG. 3, the layout 300 can further include patterns for forming source/drain contact structures 350, 352, 354, 356, 358, and 360, respectively. Such source/drain contact structures 350 to 360 are each sometimes referred to as MD. In general, each of these MDs 350 to 360 is configured to electrically connect the source/drain terminal of a corresponding transistor to an upper or lower interconnect structure. Each of the MDs 350 to 360 can be physically coupled to or wrap around the corresponding epitaxial structure. In some embodiments, each of the MDs 350 to 360 can laterally extend along the same direction as the gate structures 330-340, e.g., the Y-direction.

For example, in FIG. 3, the MD 350 is coupled to a top surface of one of the source/drain terminals of the transistor PG1, while the MD 352 is coupled to a top surface of the other source/drain terminal of the transistor PG1 (also one of the source/drain terminals of the transistor PD1); the MD 354 is coupled to a top surface of the other of the source/drain terminals of the transistor PD1; the MD 360 is coupled to a top surface of one of the source/drain terminals of the transistor PG2, while the MD 358 is coupled to a top surface of the other source/drain terminal of the transistor PG2 (also one of the source/drain terminals of the transistor PD2); and the MD 356 is coupled to a top surface of the other of the source/drain terminals of the transistor PD2.

The layout 300 can further include patterns for forming internal contact structures 362 and 364, respectively; patterns for forming interconnect structures 370, 372, 374, and 376 in the third level on the frontside, respectively; and patterns for forming via structures 377, 379, 381, and 383, respectively. In some embodiments, on the front side, each of the internal contact structures 362 and 364 can vertically extend from the first level to the second level (sometimes referred to as MDLI). Each of the via structures 377 and 379 is typically formed above a gate structure or upwardly extends from the gate structure (sometimes referred to as VG). The VGs 377 and 379 are each couped to the corresponding gate structure. Each of the via structures 381 and 383 is typically formed above an MD or upwardly extends from the MD (sometimes referred to as VD). The VDs 381 and 383 are each couped to the corresponding MD.

The third level, disposed over the second level on the frontside, may sometimes be referred to as a bottommost one of plural frontside metallization layers, e.g., M0 layer, and the interconnect structures 370 to 376 disposed therein are each sometimes referred to as an M0 track. The frontside metallization layer typically includes one or more dielectric materials (e.g., silicon, oxide, a low-k dielectric material, or the like) embedding the corresponding metal tracks formed of, e.g., copper. These M0 tracks 370 to 376 can extend along the X-direction, as shown in FIG. 3.

In some embodiments, the M0 tracks 370 and 376 can each be coupled to a corresponding one of the overlaid gate structure (or gate section) in the second level on the frontside through a VG, and the M0 tracks 372 and 374 can each be coupled to a corresponding one of the overlaid MDs in the second level on the frontside through a VD. For example, the M0 track 370 is coupled to the gate section 330A through the VG 377; the M0 track 376 is coupled to the gate section 340B through the VG 379; the M0 track 372 is coupled to the MD 350 through the VD 381; and the M0 track 374 is coupled to the MD 360 through the VD 383. The M0 tracks 370 and 376 can each operatively serve a part of the WL (FIG. 1), the M0 track 372 can operatively serve as a part of the BL (FIG. 1), and the M0 track 374 can operatively serve as a part of the BLB (FIG. 1).

The internal contact structure 362 can downwardly extend from the second level to the first level, so as to couple the MD 352 (which is coupled to the common source/drain terminals of the transistors PD1 and PG1) at the second level to the source/drain terminal of the transistor PU1 at the first level. As described above, the source/drain terminal of the transistor PU1 (the first epitaxial structure formed from the active region 210 and above the MD 252) is coupled to the gate terminal of the transistor PU2 (the gate section 230B) through the MD 252, the internal contact structure 270, and the BM0 track 272; and the gate terminal of the transistor PU2 (gate section 230B) is coupled to the gate terminal of the transistor PD2 (gate section 330B). As such, the internal node 110, that connects the common source/drain terminals of the transistors PU1, PD1, and PG1 to the gate terminals of the transistors PU2 and PD2, can be operatively formed.

Similarly, the internal contact structure 364 can downwardly extend from the second level to the first level, so as to couple the MD 358 (which is coupled to the common source/drain terminals of the transistors PD2 and PG2) at the second level to the source/drain terminal of the transistor PU2 at the first level. As described above, the source/drain terminal of the transistor PU2 (the first epitaxial structure formed from the active region 220 and above the MD 252) is coupled to the gate terminal of the transistor PU2 (the gate section 230B) through the MD 258, the internal contact structure 274, and the BM0 track 276; and the gate terminal of the transistor PU1 (gate section 240A) is coupled to the gate terminal of the transistor PD1 (gate section 340A). As such, the internal node 112, that connects the common source/drain terminals of the transistors PU2, PD2, and PG2 to the gate terminals of the transistors PU1 and PD1, can be operatively formed.

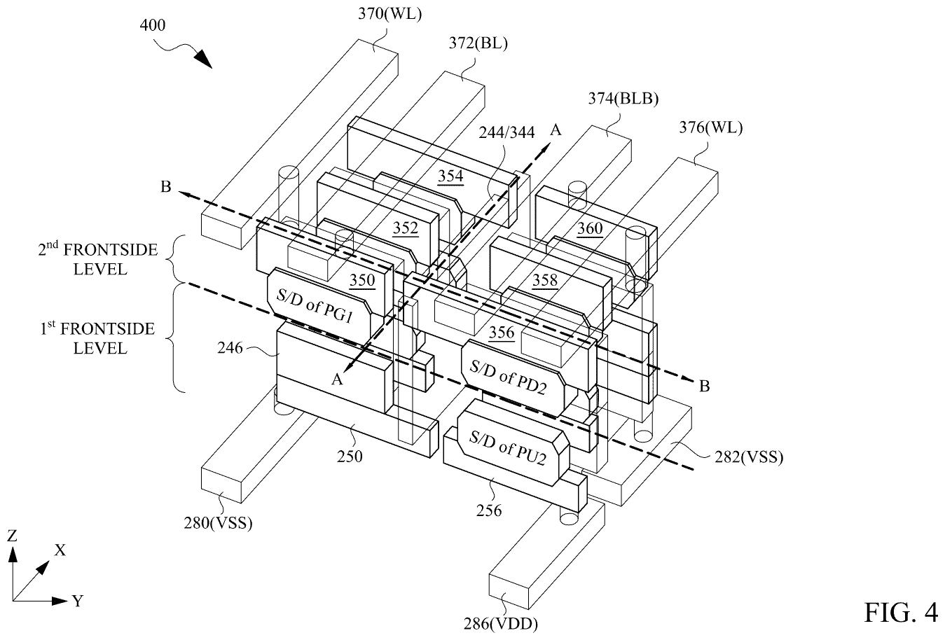

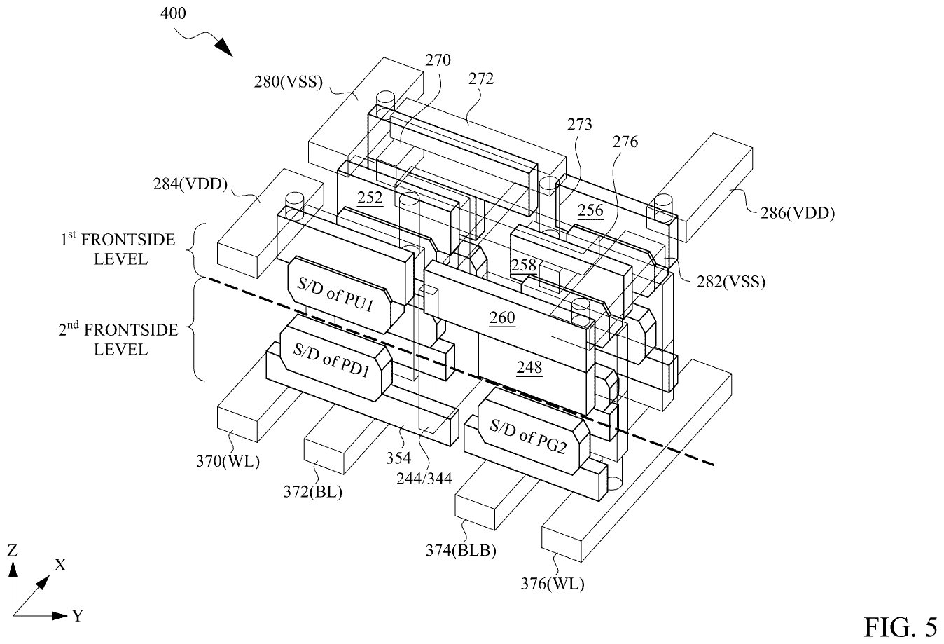

FIG. 4 and FIG. 5 respectively illustrate perspective views of a semiconductor device 400 including a memory cell configured with a CFET structure, in accordance with some embodiments of the present disclosure. For example, the semiconductor device 400 may include the memory cell 100 formed based on the layouts 200-300 (FIGS. 2-3), and thus, some of the reference numerals of FIGS. 2-3 may be again used. Specifically, the perspective view of FIG. 4 is viewed from the frontside of a substrate (where the transistors of the memory cell 100 are formed), and the perspective view of FIG. 5 is viewed from the backside of the substrate. It should be appreciated that the semiconductor device 400 of FIGS. 4-5 has been simplified, and thus, some of the above-described structures are omitted for purposes of clarity.

As shown, the wall structure 244/344 vertically extends to connect the MD 354 and MD 356 at the second frontside level to the MD 250 (not shown in FIG. 5) and MD 260 (not shown in FIG. 4) at the first level. The MD 356 is connected to one of the source/drain terminals of the transistor PD2, and the MD 354 is connected to one of the source/drain terminals of the transistor PD1. The MD 250 is coupled to the BM0 track 280 that carries the ground voltage VSS, and the MD 260 is coupled to the BM0 track 282 that carries the ground voltage VSS. As such, those source/drain terminals of the transistors PD1 and PD2 can be electrically connected to the ground voltage VSS through the wall structure 244/344. Further, it should be noted that the MD 250 has its top surface connected to the isolation structure 246 (e.g., FIG. 4), and the MD 260 has its top surface connected to the isolation structure 248 (e.g., FIG. 5). Specifically, in FIG. 5, the internal contact structure 270, the BM0 track 272, and the BVG 273 can form a part of the connection between one of the source/drain terminals of the transistor PU1 and the gate terminal of the transistor PU2; and the internal contact structure 274, the BM0 track 276, and the BVG 277 can form a part of the connection between one of the source/drain terminals of the transistor PU2 and the gate terminal of the transistor PU1.

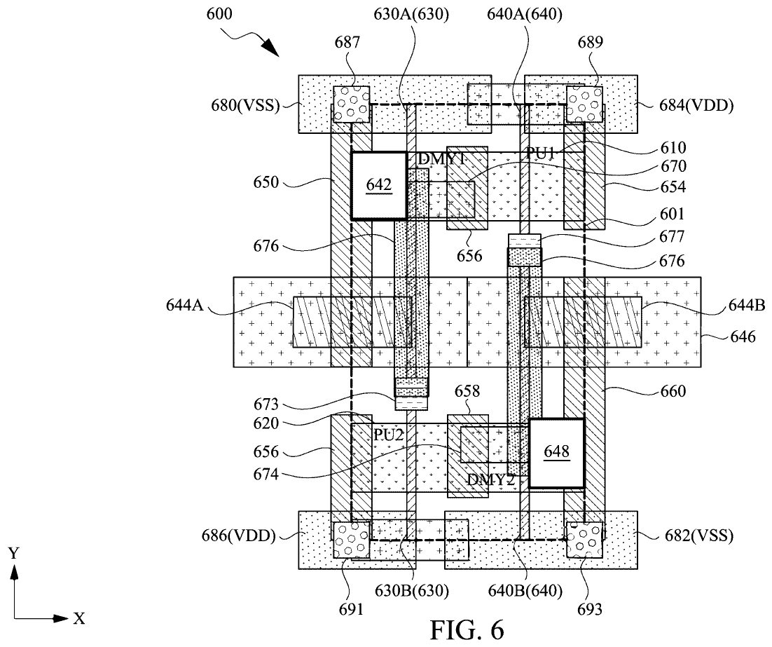

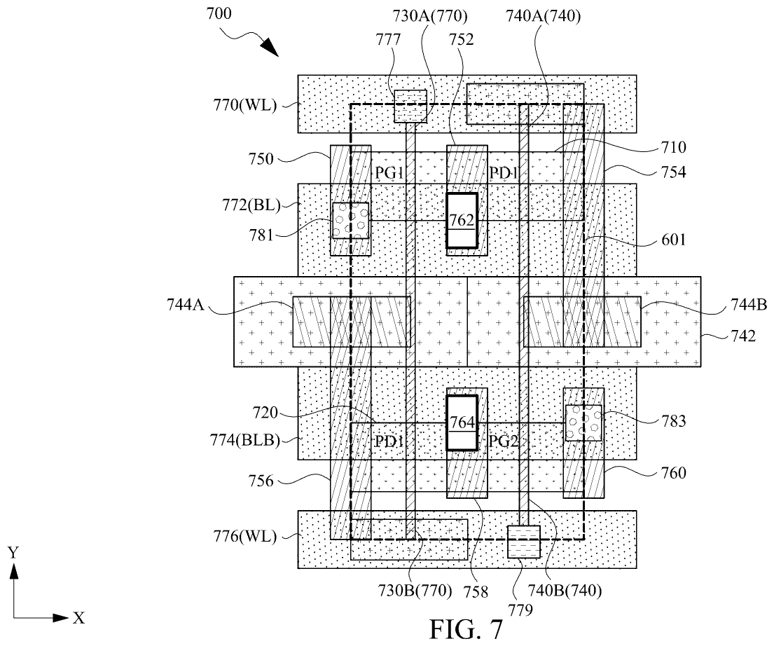

FIG. 6 and FIG. 7 respectively illustrate layouts 700 and 800, which can be collectively utilized to form the memory cell 100 (FIG. 1) configured in a CFET structure with an embedded power structure, in accordance with some embodiments. The CFET structure can include a number of first transistors disposed at a first level on the frontside of a substrate, and a number of second transistors disposed at a second, upper level on the frontside of the substrate. In some embodiments, each of these first and second transistors is configured as a GAA FET, with the first transistors and the second transistors having opposite conductive types. In some other embodiments, each of the first and second transistors can be formed as other type of transistor structures, while remaining within the scope of the present disclosure.

As depicted in FIGS. 6-7, each of the layouts 600 and 700 can include a cell boundary 601 defining a physical area of the memory cell 100. The embedded power structure can be formed as a pair of via structures vertically extending from the first level to the second level. Further, when viewed from the top, such a pair of via structures can be disposed within the cell boundary 601 of the memory cell 100. For example, the via structures may laterally extend along a middle line of the cell boundary 601, with the transistors disposed on the opposite sides of the middle line, respectively. The middle line can cross the cell boundary in a first lateral direction, with edges of the cell boundary that extend along a second lateral direction perpendicular to the first lateral direction disposed on lengthwise ends of the middle line, respectively. The pair of via structures can be disposed around those edges, respectively.

Generally, each of the layouts 600 and 700 can include a number of patterns configured for forming respective structures, and thus, such patterns of the disclosed layout are herein referred to as the structures to be formed, respectively, in the following discussion. For example, the layout 600 includes patterns configured to form structures of the first transistors at the first level on the frontside; and the layout 700 includes patterns configured to form structures of the second transistors at the second level on the frontside. Further, the layout 600 includes patterns configured to form contact/via/interconnect structures disposed on a backside of the substrate (e.g., at a first level on the backside); and the layout 700 includes patterns configured to form via/interconnect structures at a third level on the frontside (e.g., over the second level). It should be understood that each of the layouts 600 and 700 has been simplified for illustrative purposes, and thus, can include any of various other patterns while remaining within the scope of the present disclosure.

Referring first to FIG. 6, the layout 600 can include patterns for forming active regions 610 and 620 and gate structures 630 and 640, respectively. The active regions 610 and 620 may extend in the X-direction (e.g., a first lateral direction); and the gate structures 630 and 640 may extend in the Y-direction (e.g., a second lateral direction). Each of the active regions 610 and 620 may be formed as a fin structure or a stack structure extending along the X-direction, and each of the gate structures 630 and 640 may be formed to extend in the Y-direction to traverse the active regions 610 and 620.

The layout 600 can further include a number of cut patterns (e.g., 642), each of which extends along the X-direction traversing one or more of the gate structures 630-640. As shown, the cut pattern 642, extending along the X-direction to traverse both the gate structures 630-640, can be configured to define the footprint of a dielectric structure (hereinafter “dielectric structure 642”). The dielectric structure 642 can be formed along the middle line of the boundary 601, so as to divide each of the gate structures 630-640 into separate gate sections, e.g., gate sections 630A and 630B and gate sections 640A and 640B. A power structure, implemented as a first via structure 644A and 644B vertically extending, can be formed to extend through the dielectric structure 642.

Referring next to FIG. 7, the layout 700 can include patterns for forming active regions 710 and 720 and gate structures 730 and 740, respectively. The active regions 710 and 720 may extend in the X-direction; and the gate structures 730 and 740 may extend in the Y-direction. Each of the active regions 710 and 720 may be formed as a fin structure or a stack structure extending along the X-direction, and each of the gate structures 730 and 740 may be formed to extend in the Y-direction to traverse the active regions 710 and 720.

The layout 700 can further include a number of cut patterns (e.g., 742), each of which extends along the X-direction traversing one or more of the gate structures 730-740. As shown, the cut pattern 742, extending along the X-direction to traverse both the gate structures 730-740, can be configured to define the footprint of a dielectric structure (hereinafter “dielectric structure 742”). The dielectric structure 742 can be formed along the middle line of the boundary 601, so as to divide each of the gate structures 730-740 into separate gate sections, e.g., gate sections 730A and 730B and gate sections 740A and 740B. A power structure, implemented as a first via structure 744A and a second via structure 744B vertically extending, can be formed to extend through the dielectric structure 742.

In some embodiments, the active regions 610 and 710 are vertically aligned with each other, the active regions 620 and 720 are vertically aligned with each other, the gate structures 630 and 730 are vertically aligned with each other, and the gate structures 640 and 740 are vertically aligned with each other. The active regions 610 and 710 may be physically formed as a single structure (sometimes referred to as “active region 610/710”), the active regions 620 and 720 may be physically formed as a single structure (sometimes referred to as “active region 620/720”), the gate structures 630 and 730 may be physically formed as a single structure (sometimes referred to as “gate structure 630/730”), and the gate structures 640 and 740 may be physically formed as a single structure (sometimes referred to as “gate structure 640/740”.

Further, in some embodiments, the dielectric structures 642 and 742 are vertically aligned with each other, and the via structures 644A-B and 744A-B, respectively disposed in the dielectric structures 642 and 742, are vertically aligned with each other. For example, the via structures 644A and 744A are vertically aligned with each other, and the via structures 644B and 744B are vertically aligned with each other. The dielectric structures 642 and 742 may be physically formed as a single structure (sometimes referred to as “dielectric structure 642/742”), the via structures 644A and 744A may be physically formed as a single structure (sometimes referred to as “via structure 644A/744”), and the via structures 644B and 744B may be physically formed as a single structure (sometimes referred to as “via structure 644B/744B”).

As such, the dielectric structure 642/742, the via structures 644A/744A, and the via structures 644B/744B can vertically extend from the first level to the second level, such that the dielectric structure 642/742 can cut the gate structure 630 into the gate sections 630A and gate sections 630B, the gate structure 730 into the gate sections 730A and gate sections 730B, the gate structure 640 into the gate sections 640A and gate sections 640B, and the gate structure 740 into the gate sections 740A and gate sections 740B. In some embodiments, the gate sections 630A and 730A can be coupled to each other (sometimes referred to as “gate section 630A/730A”), the gate sections 630B and 730B can be coupled to each other (sometimes referred to as “gate section 630B/730B”), the gate sections 640A and 740A can be coupled to each other (sometimes referred to as “gate section 640A/740A”), and the gate sections 640B and 740B can be coupled to each other (sometimes referred to as “gate section 640B/740B”).

For example, the active region 610/710 and active region 620/720 can each be first formed as a stack structure protruding from the frontside surface of a substrate. The stack may include a number of first semiconductor nanostructures (e.g., first nanosheets) extending along the X-direction and vertically separated from each other, and a number of second semiconductor nanostructures (e.g., second nanosheets) extending along the X-direction and vertically separated from each other. The first nanosheets are positioned at the first level, and the second nanosheets are positioned at the second level. According to some embodiments of the present disclosure, the first nanosheets, formed based on a lower portion of the active region 610/710 or a lower portion of the active region 620/720, can partially form the first transistors at the first level; and the second nanosheets, formed based on an upper portion of the active region 610/710 or an upper portion of the active region 620/720, can partially form the second transistors at the second level. Further, the first nanosheets and the second nanosheets can be vertically aligned with but separated from each other, with at least one dielectric layer interposed therebetween.

Next, respective portions of the first and second nanosheets in each of the stacks that are overlaid by the gate structure 630/730 and the gate structure 640/740, which are initially formed as a number of dummy (e.g., polysilicon) gate structures, respectively, may remain. Other portions of the first nanosheets are replaced with a number of first epitaxial structures, and other portions of the second nanosheets are replaced with a number of second epitaxial structures. According to some embodiments of the present disclosure, the first epitaxial structures (at the first level) may be formed with a p-type conductivity, and the second epitaxial structures (at the second level) may be formed with an n-type conductivity. The first epitaxial structures can operatively form respective source/drain terminals of the first transistors at the first level, and the second epitaxial structures can operatively form respective source/drain terminals of the second transistors at the second level.

Next, each of the dummy gate structures 630/730 and 640/740 can be replaced by a corresponding active (e.g., metal) gate structure to form the first and second transistors. According to some embodiments of the present disclosure, each of the active gate structures can include a lower portion and an upper portion corresponding to the first level and the second level, respectively. For example, the lower portion of the active gate structure (e.g., corresponding to the gate section 630A, 630B, 640A, or 640B) may include one or more first work function metals configured for forming a gate terminal of one of the first transistors with the p-type conductivity, and the upper portion of the active gate structure (e.g., corresponding to the gate section 730A, 730B, 740A, or 740B) may include one or more second work function metals configured for forming a gate terminal of one of the second transistors with the n-type conductivity. Details of a series of manufacturing processes to form a semiconductor device that includes the structures of first transistors at a first level and second transistors at a second level will be described with respect to FIGS. 6 and 7.

As a brief overview, the transistors PU1 and PU2 of the memory cell 100 (FIG. 1) can be formed at the first level based on the layout 600 (as indicated in FIG. 6), and the transistors PG1, PG2, PD1, and PD2 of the memory cell 100 (FIG. 1) can be formed at the second level based on the layout 700 (as indicated in FIG. 7). In some embodiments, the transistors PU1 and PU2 at the first level can be formed with the p-type conductivity, and the transistors PG1, PG2, PD1, and PD2 at the second level can be formed with the n-type conductivity. Further, a first dummy transistor DMY1 and a second dummy transistor DMY2, each of which has one of its first epitaxial structures (e.g., source/drain terminals) replaced with an isolation structure, can be formed at the first level.

For example, in FIG. 6, the transistor PU1 can include its channel, gate terminal, and source/drain terminals formed by a subset of the first nanosheets in the active region 610, the gate section 640A, and a subset of the first epitaxial structures formed from the active region 610 and disposed on opposite sides of the gate section 640A, respectively. The transistor PU2 can include its channel, gate terminal, and source/drain terminals formed by a subset of the first nanosheets in the active region 620, the gate section 630B, and a subset of the first epitaxial structures formed from the active region 620 and disposed on opposite sides of the gate section 630B, respectively. The transistor DMY1 can include its channel, gate terminal, and source/drain terminals formed by a subset of the first nanosheets in the active region 610, the gate section 630A, and a subset of the first epitaxial structures formed from the active region 610 and disposed on opposite sides of the gate section 630A, respectively. In some embodiments, one of the source/drain terminals (e.g., the first epitaxial structure disposed opposite the gate section 630A from the gate section 640A) of the transistor DMY1 can be replaced with isolation structure 646. The transistor DMY2 can include its channel, gate terminal, and source/drain terminals formed by a subset of the first nanosheets in the active region 620, the gate section 640B, and a subset of the first epitaxial structures formed from the active region 620 and disposed on opposite sides of the gate section 640B, respectively. In some embodiments, one of the source/drain terminals (e.g., the first epitaxial structure disposed opposite the gate section 640B from the gate section 630B) of the transistor DMY2 can be replaced with isolation structure 648.

In another example, in FIG. 7, the transistor PD1 can include its channel, gate terminal, and source/drain terminals formed by a subset of the second nanosheets in the active region 710, the gate section 740A, and a subset of the second epitaxial structures formed from the active region 710 and disposed on opposite sides of the gate section 740A, respectively. The transistor PG1 can include its channel, gate terminal, and source/drain terminals formed by a subset of the second nanosheets in the active region 710, the gate section 730A, and a subset of the second epitaxial structures formed from the active region 710 and disposed on opposite sides of the gate section 730A, respectively. The transistor PD2 can include its channel, gate terminal, and source/drain terminals formed by a subset of the second nanosheets in the active region 720, the gate section 730B, and a subset of the second epitaxial structures formed from the active region 720 and disposed on opposite sides of the gate section 730B, respectively. The transistor PG2 can include its channel, gate terminal, and source/drain terminals formed by a subset of the second nanosheets in the active region 720, the gate section 740B, and a subset of the second epitaxial structures formed from the active region 720 and disposed on opposite sides of the gate section 740B, respectively.

Referring again to FIG. 6, the layout 600 can further include patterns for forming source/drain contact structures 650, 652, 654, 656, 658, and 660, respectively. Such source/drain contact structures 650 to 660 are each sometimes referred to as MD. In general, each of these MDs 650 to 660 is configured to electrically connect the source/drain terminal of a corresponding transistor to an upper or lower interconnect structure. However, some of the MDs 650 to 660 (e.g., 650, 660) may each be physically coupled to a corresponding isolation structure that replaces an epitaxial structure (e.g., 646, 648), according to some embodiments of the present disclosure. Each of the MDs 650 to 660 can be physically coupled to or wrap around the corresponding epitaxial structure or isolation structure. In some embodiments, each of the MDs 650 to 660 can laterally extend along the same direction as the gate structures 630-640, e.g., the Y-direction.

For example, in FIG. 6, the MD 650 is coupled to a bottom surface of the isolation structure 646; the MD 660 is coupled to a bottom surface of the isolation structure 648; the MD 654 is coupled to a bottom surface of one of the source/drain terminals of the transistor PU1, while the MD 652 is coupled to a bottom surface of the other source/drain terminal of the transistor PU1; and the MD 656 is coupled to a bottom surface of one of the source/drain terminals of the transistor PU2, while the MD 658 is coupled to a bottom surface of the other source/drain terminal of the transistor PU2.

The layout 600 can further include patterns for forming internal contact structures 670 and 674, respectively; patterns for forming interconnect structures 672, 676, 680, 682, 684, and 686 in the first level on the backside, respectively; and patterns for forming via structures 673, 677, 687, 689, 691, and 693, respectively. In some embodiments, each of the internal contact structures 670 and 674 can be formed below and coupled to an MD. Further, the internal contact structures 670 and 674 can each extend along the X-direction to connect to an interconnect structure formed underneath (e.g., a BM0 track), which will be discussed below. In some embodiments, each of the internal contact structures 670 and 674 may be vertically disposed between an MD and a BM0 track. For example, the internal contact structures 670 and 674 may be vertically interposed between a backside surface of the substrate and the BM0 layer. Each of the via structures 673 and 677 is typically formed below a gate structure or downwardly extends from the gate structure (sometimes referred to as BVG). The BVGs 673 and 677 are each coupled to the corresponding gate structure. Each of the via structures 687 to 693 is typically formed below an MD or downwardly extends from the MD (sometimes referred to as BVD). The BVDs 687 to 693 are each couped to the corresponding MD.

The first level, disposed on the backside, may sometimes be referred to as a bottommost one of plural backside metallization layers, e.g., BM0 layer, and the interconnect structures 672, 676, 680, 682, 684, and 686 disposed therein are each sometimes referred to as a BM0 track. The backside metallization layer typically includes one or more dielectric materials (e.g., silicon, oxide, a low-k dielectric material, or the like) embedding the corresponding metal tracks formed of, e.g., copper. These BM0 tracks 672, 676, 680, 682, 684, and 686 (including the internal contact structures 670 and 674) can extend along the X-direction or the Y-direction, as shown in FIG. 6.

In some embodiments, the BM0 tracks 672 and 676 can each be coupled to a corresponding one of the overlaying gate structure (or gate section) in the first level on the frontside through a BVG, and the BM0 tracks 680 to 686 can each be coupled to a corresponding one of the overlaying MDs in the first level on the frontside through a BVD. For example, the BM0 track 680 is coupled to the MD 650 through the BVD 687; the BM0 track 682 is coupled to the MD 660 through the BVD 693; the BM0 track 684 is coupled to the MD 654 through the BVD 689; and the BM0 track 686 is coupled to the MD 656 through the BVD 691. The BM0 tracks 680 and 682 can each operatively serve a part of a power rail carrying the ground voltage VSS, and the BM0 tracks 684 and 686 can each operatively serve as another power rail carrying the supply voltage VDD.

In some embodiments, these power rails (e.g., 680 to 686) may be disposed at the corners of the boundary 601, respectively, with the BM0 tracks (VSS) 680 and 682 disposed diagonally opposite to each other and the BM0 tracks (VDD) 684 and 686 disposed diagonally opposite to each other. With the MDs 650 and 660 disposed along the Y-direction, the via structure 644A/744A, disposed along the middle line of the boundary 601, can be coupled to the BM0 track (VSS) 680 that extends along the X-direction, and the via structure 644B/744B, disposed along the middle line of the boundary 601, can be coupled to the BM0 track (VSS) 682 that extends along the X-direction. For example, the MDs 650 and 660 can be coupled to (or overlapped with when viewed from the top/bottom) the via structure 644A/744A and the via structure 644B/744B, as shown in FIGS. 6-7. Along each of its lengthwise direction (e.g., the Y-direction), the MDs 650 and 660 can couple the via structure 644A/744A to the BM0 track (VSS) 680 and the via structure 644B/744B to the BM0 track (VSS) 682, respectively.

Further, the internal contact structure 670 can be coupled to the BM0 track 672 that is coupled to the gate terminal of the transistor PU2, and the internal contact structure 674 can be coupled to the BM0 track 676 that is coupled to the gate terminal of the transistor PU1. As the internal contact structure 670 extends in the X-direction and the BM0 track 672 extends in the Y-direction, the internal contact structure 670 and the BM0 track 672 can collectively form an L-shaped profile, when viewed from the top or bottom. Similarly, the internal contact structure 674 and the BM0 track 676 can collectively form another L-shaped profile, when viewed from the top or bottom. In some other embodiments, the internal contact structure 670 and the BM0 track 672 can be formed in the same level, e.g., an intermediate level vertically between the backside surface of the substrate and the BM0 layer. Similarly, the internal contact structure 674 and the BM0 track 676 can be formed in the same intermediate level.

As such, connection between one of the source/drain terminals of the transistor PU1 and the gate terminal of the transistor PU2 (or the internal node 110 of FIG. 1) can be operatively formed at least by the MD 652 (connected to that source/drain terminal of the transistor PU1), the internal contact structure 670, the BM0 track 672, and the BVG 673 (connected to the gate terminal of the transistor PU2); and connection between one of the source/drain terminals of the transistor PU2 and the gate terminal of the transistor PU1 (or the internal node 112 of FIG. 1) can be operatively formed at least by the MD 658 (connected to that source/drain terminal of the transistor PU2), the internal contact structure 674, the BM0 track 676, and the BVG 677 (connected to the gate terminal of the transistor PU1).

Referring again to FIG. 7, the layout 700 can further include patterns for forming source/drain contact structures 750, 752, 754, 756, 758, and 760, respectively. Such source/drain contact structures 750 to 760 are each sometimes referred to as MD. In general, each of these MDs 750 to 760 is configured to electrically connect the source/drain terminal of a corresponding transistor to an upper or lower interconnect structure. Each of the MDs 750 to 760 can be physically coupled to or wrap around the corresponding epitaxial structure. In some embodiments, each of the MDs 750 to 760 can laterally extend along the same direction as the gate structures 730-740, e.g., the Y-direction.

For example, in FIG. 7, the MD 750 is coupled to a top surface of one of the source/drain terminals of the transistor PG1, while the MD 752 is coupled to a top surface of the other source/drain terminal of the transistor PG1 (also one of the source/drain terminals of the transistor PD1); the MD 754 is coupled to a top surface of the other of the source/drain terminals of the transistor PD1; the MD 760 is coupled to a top surface of one of the source/drain terminals of the transistor PG2, while the MD 758 is coupled to a top surface of the other source/drain terminal of the transistor PG2 (also one of the source/drain terminals of the transistor PD2); and the MD 756 is coupled to a top surface of the other of the source/drain terminals of the transistor PD2.

The layout 700 can further include patterns for forming internal contact structures 762 and 764, respectively; patterns for forming interconnect structures 770, 772, 774, and 776 in the third level on the frontside, respectively; and patterns for forming via structures 777, 779, 781, and 783, respectively. In some embodiments, on the front side, each of the internal contact structures 762 and 764 can vertically extend from the first level to the second level sometimes referred to as MDLI). Each of the via structures 777 and 779 is typically formed above a gate structure or upwardly extends from the gate structure (sometimes referred to as VG). The VGs 777 and 779 are each couped to the corresponding gate structure. Each of the via structures 781 and 783 is typically formed above an MD or upwardly extends from the MD (sometimes referred to as VD). The VDs 781 and 783 are each couped to the corresponding MD.

The third level, disposed over the second level on the frontside, may sometimes be referred to as a bottommost one of plural frontside metallization layers, e.g., M0 layer, and the interconnect structures 770 to 776 disposed therein are each sometimes referred to as an M0 track. The frontside metallization layer typically includes one or more dielectric materials (e.g., silicon, oxide, a low-k dielectric material, or the like) embedding the corresponding metal tracks formed of, e.g., copper. These M0 tracks 770 to 776 can extend along the X-direction, as shown in FIG. 7.

In some embodiments, the M0 tracks 770 and 776 can each be coupled to a corresponding one of the overlaid gate structure (or gate section) in the second level on the frontside through a VG, and the M0 tracks 772 and 774 can each be coupled to a corresponding one of the overlaid MDs in the second level on the frontside through a VD. For example, the M0 track 770 is coupled to the gate section 730A through the VG 777; the M0 track 776 is coupled to the gate section 740B through the VG 779; the M0 track 772 is coupled to the MD 750 through the VD 781; and the M0 track 774 is coupled to the MD 760 through the VD 783. The M0 tracks 770 and 776 can each operatively serve a part of the WL (FIG. 1), the M0 track 772 can operatively serve as a part of the BL (FIG. 1), and the M0 track 774 can operatively serve as a part of the BLB (FIG. 1).

The internal contact structure 762 can downwardly extend from the second level to the first level, so as to couple the MD 752 (which is coupled to the common source/drain terminals of the transistors PD1 and PG1) at the second level to the source/drain terminal of the transistor PU1 at the first level. As described above, the source/drain terminal of the transistor PU1 (the first epitaxial structure formed from the active region 610 and above the MD 652) is coupled to the gate terminal of the transistor PU2 (the gate section 630B) through the MD 652, the internal contact structure 670, and the BM0 track 672; and the gate terminal of the transistor PU2 (gate section 630B) is coupled to the gate terminal of the transistor PD2 (gate section 730B). As such, the internal node 110, that connects the common source/drain terminals of the transistors PU1, PD1, and PG1 to the gate terminals of the transistors PU2 and PD2, can be operatively formed.

Similarly, the internal contact structure 764 can downwardly extend from the second level to the first level, so as to couple the MD 758 (which is coupled to the common source/drain terminals of the transistors PD2 and PG2) at the second level to the source/drain terminal of the transistor PU2 at the first level. As described above, the source/drain terminal of the transistor PU2 (the first epitaxial structure formed from the active region 620 and above the MD 652) is coupled to the gate terminal of the transistor PU2 (the gate section 630B) through the MD 658, the internal contact structure 674, and the BM0 track 676; and the gate terminal of the transistor PU1 (gate section 640A) is coupled to the gate terminal of the transistor PD1 (gate section 740A). As such, the internal node 112, that connects the common source/drain terminals of the transistors PU2, PD2, and PG2 to the gate terminals of the transistors PU1 and PD1, can be operatively formed.

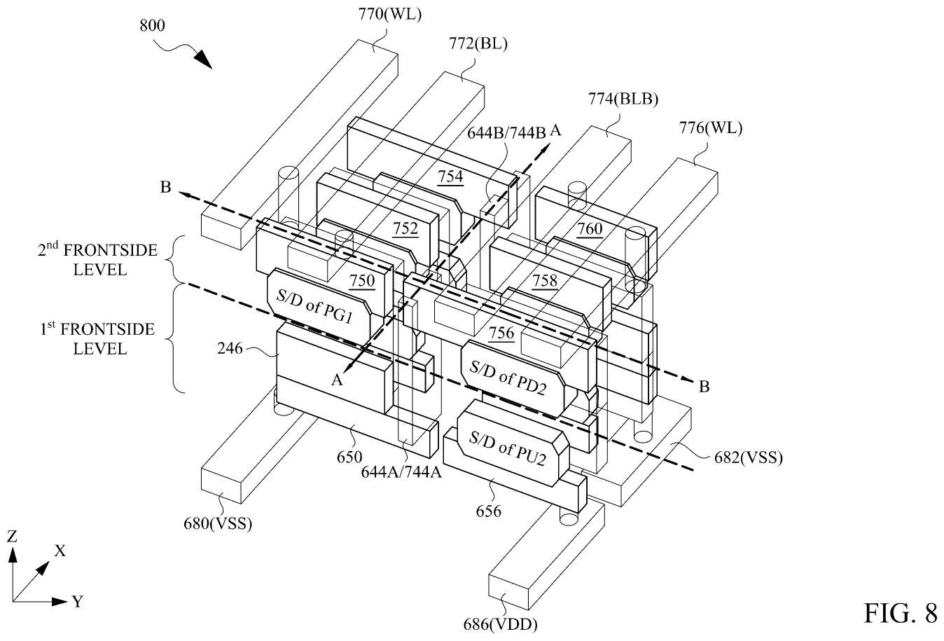

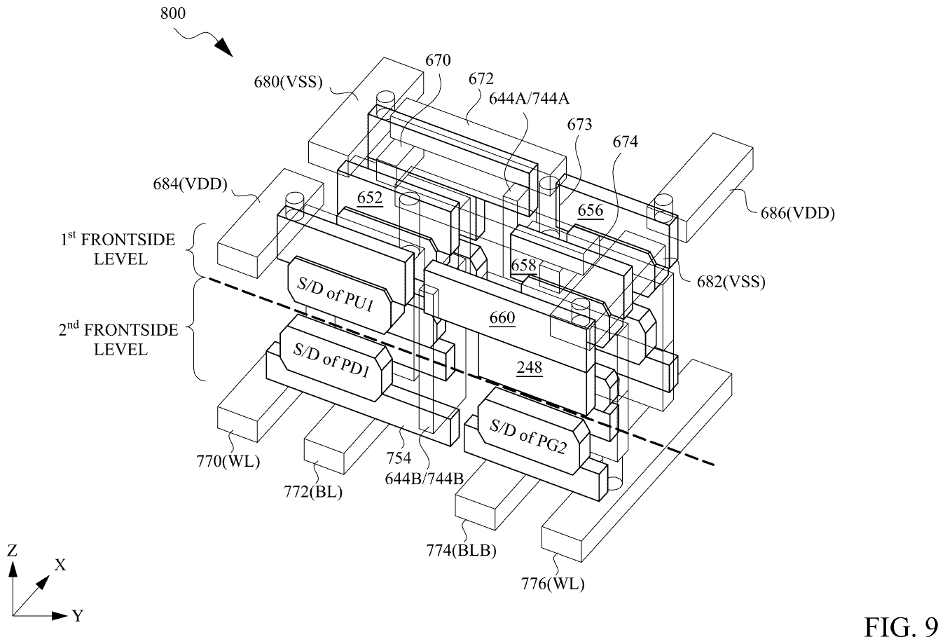

FIG. 8 and FIG. 9 respectively illustrate perspective views of a semiconductor device 800 including a memory cell configured with a CFET structure, in accordance with some embodiments of the present disclosure. For example, the semiconductor device 800 may include the memory cell 100 formed based on the layouts 600-700 (FIGS. 6-7), and thus, some of the reference numerals of FIGS. 6-7 may be again used. Specifically, the perspective view of FIG. 8 is viewed from the frontside of a substrate (where the transistors of the memory cell 100 are formed), and the perspective view of FIG. 9 is viewed from the backside of the substrate. It should be appreciated that the semiconductor device 800 of FIGS. 8-9 has been simplified, and thus, some of the above-described structures are omitted for purposes of clarity.

As shown, the via structure 644A/744A vertically extends to connect the MD 756 at the second frontside level to the MD 650 (not shown in FIG. 9) at the first level, and the via structure 644B/744B vertically extends to connect the MD 754 at the second frontside level to the MD 660 (not shown in FIG. 8) at the first level. The MD 756 is connected to one of the source/drain terminals of the transistor PD2, and the MD 650 is coupled to the BM0 track 680 that carries the ground voltage VSS. The MD 754 is connected to one of the source/drain terminals of the transistor PD1, and the MD 660 is coupled to the BM0 track 682 that carries the ground voltage VSS. As such, those source/drain terminals of the transistors PD1 and PD2 can be electrically connected to the ground voltage VSS through the via structure 644A/744A and via structure 644B/744B, respectively. Further, it should be noted that the MD 650 has its top surface connected to the isolation structure 646 (e.g., FIG. 8), and the MD 660 has its top surface connected to the isolation structure 648 (e.g., FIG. 9). Specifically, in FIG. 9, the internal contact structure 670, the BM0 track 672, and the BVG 673 can form a part of the connection between one of the source/drain terminals of the transistor PU1 and the gate terminal of the transistor PU2; and the internal contact structure 674, the BM0 track 676, and the BVG 677 can form a part of the connection between one of the source/drain terminals of the transistor PU2 and the gate terminal of the transistor PU1.

FIG. 10 and FIG. 11 respectively illustrate cross-sectional views of the semiconductor device 400 shown in FIGS. 4-5, in accordance with some embodiments. For example, the cross-sectional view of FIG. 10 is cut along line A-A indicated in FIG. 4 (e.g., the X-direction), and the cross-sectional view of FIG. 11 is cut along line B-B of line B-B indicated in FIG. 4 (e.g., the Y-direction).

In FIG. 10, the wall structure 244/344 vertically extends (e.g., through the first and second frontside levels) to connect the MDs 250 and 260 to the MDs 356 and 354. In some embodiments, the MDs 250 and 260 can laterally extend toward opposite directions, and the MDs 356 and 354 can laterally extend toward opposite directions, as better appreciated in FIGS. 4-5. In FIG. 11, the wall structure 244/344 vertically extends (e.g., through the first and second frontside levels) to connect the MD 250 to the MD 356. In some embodiments, the MD 250 may be coupled to the isolation structure 246, and the MD 356 may be coupled to one of the source/drain terminals of the transistor PD2. As further depicted in FIG. 11, at the first level, the MD 256, coupled to one of the source/drain terminals of the transistor PU2, is laterally separated from the MD 250; and at the second level, the MD 350, coupled to one of the source/drain terminals of the transistor PG1, is laterally separated from the MD 356.

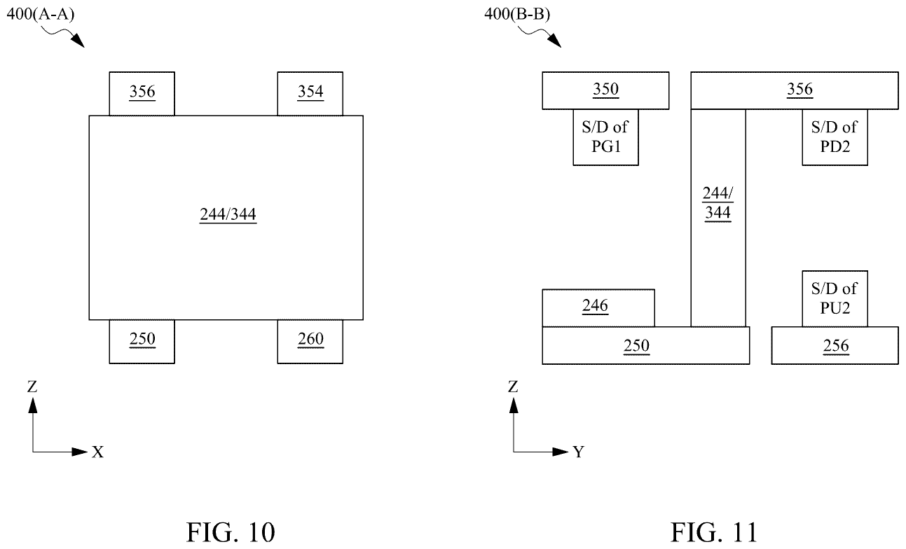

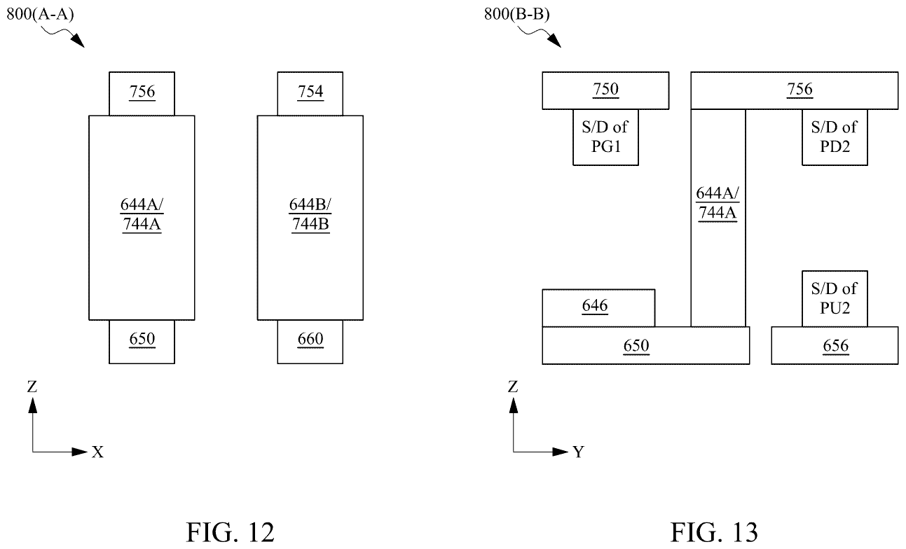

FIG. 12 and FIG. 13 respectively illustrate cross-sectional views of the semiconductor device 800 shown in FIGS. 8-9, in accordance with some embodiments. For example, the cross-sectional view of FIG. 12 is cut along line A-A indicated in FIG. 8 (e.g., the X-direction), and the cross-sectional view of FIG. 13 is cut along line B-B of line B-B indicated in FIG. 8 (e.g., the Y-direction).

In FIG. 12, the via structure 644A/744A vertically extends (e.g., through the first and second frontside levels) to connect the MD 650 to the MD 756; and the via structure 644B/744B vertically extends (e.g., through the first and second frontside levels) to connect the MD 660 to the MD 754. In some embodiments, the MDs 650 and 756 can laterally extend toward opposite directions, and the MDs 660 and 754 can laterally extend toward opposite directions, as better appreciated in FIGS. 8-9. In FIG. 13, the via structure 644A/744A vertically extends (e.g., through the first and second frontside levels) to connect the MD 650 to the MD 756. In some embodiments, the MD 650 may be coupled to the isolation structure 646, and the MD 756 may be coupled to one of the source/drain terminals of the transistor PD2. As further depicted in FIG. 13, at the first level, the MD 656, coupled to one of the source/drain terminals of the transistor PU2, is laterally separated from the MD 650; and at the second level, the MD 750, coupled to one of the source/drain terminals of the transistor PG1, is laterally separated from the MD 756.

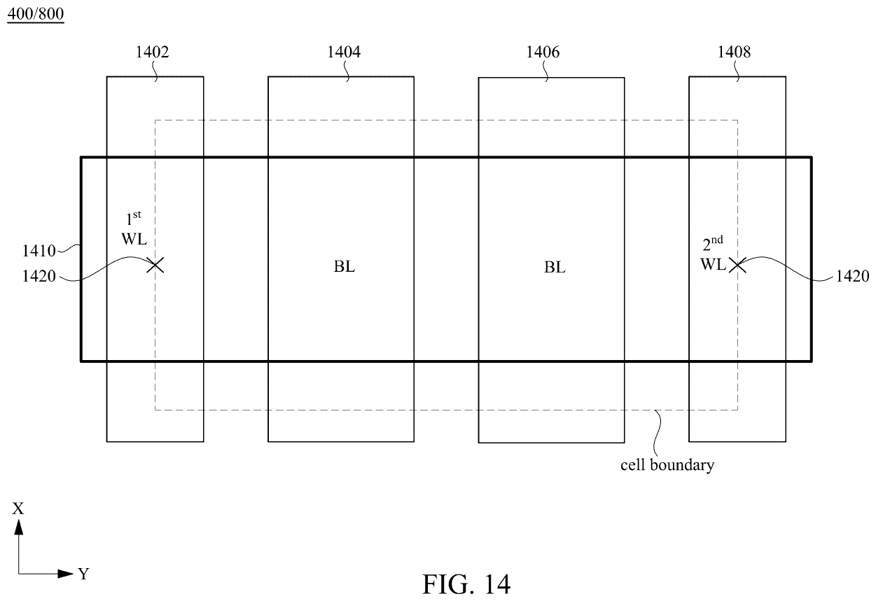

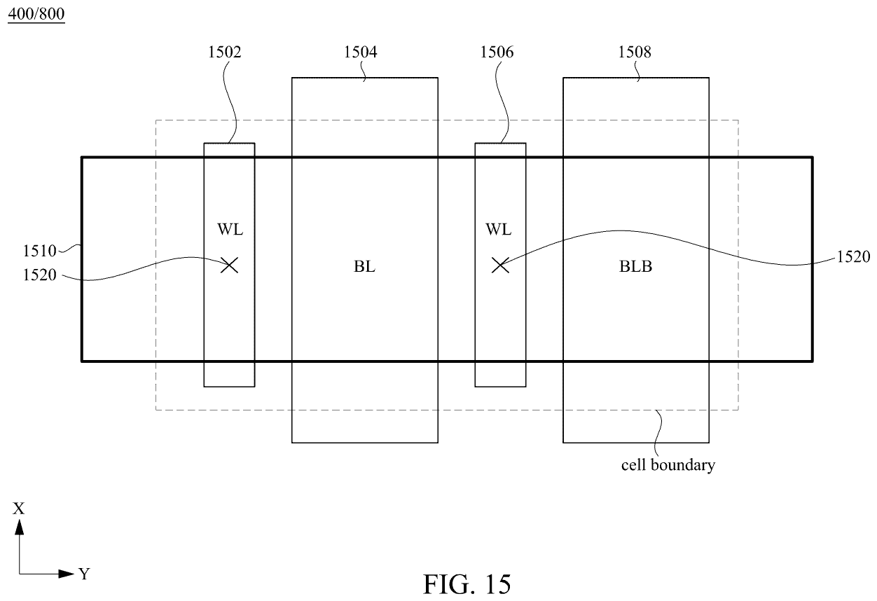

FIG. 14 and FIG. 15 respectively illustrate top views of the semiconductor device 400 (FIGS. 4-5) or 800 (FIGS. 8-9), in accordance with some embodiments. Each of the top views of FIGS. 14 and 15 includes a plural number of frontside metal tracks disposed over a memory cell. It should be understood that the top views of FIGS. 14 and 15 are provided simply for illustrative purposes, and are not intended to limit the scope of the present disclosure.

The top view of FIG. 14 refers to an arrangement of plural M0 tracks, 1402, 1404, 1406, and 1408, with respect to a corresponding cell boundary, and these M0 tracks 1402 to 1408 are configured as a first WL, a BL, a BLB, and a second WL, respectively. In some embodiments, from a leftmost edge to a rightmost edge of the cell boundary, the first WL (1402), the BL (1404), the BLB (1406), and the second WL (1408) are arranged in the order as shown. For example, the first WL, BL, BLB, and second WL of FIG. 14 can correspond to the M0 tracks 370, 372, 374, and 376, respectively, as shown in FIGS. 4-5. In another example, the first WL, BL, BLB, and second WL of FIG. 14 can correspond to the M0 tracks 770, 772, 774, and 776, respectively, as shown in FIGS. 8-9. In some embodiments, these M0 tracks can extend along the X-direction. Further, the semiconductor device 400 or 800 can further include at least one M1 track 1410 extending in the Y-direction over the first WL, BL, BLB, and second WL, and coupled to the first WL and second WL through respective via structures 1420. Such an M1 track is disposed in a next bottommost (frontside) metallization layer, typically referred to as an M1 layer.

The top view of FIG. 15 refers to another arrangement of plural M0 tracks, 1502, 1504, 1506, and 1508, with respect to a corresponding cell boundary, and these M0 tracks 1502 to 1508 are configured as a first WL, a BL, a second WL, and a BLB, respectively. In some embodiments, from a leftmost edge to a rightmost edge of the cell boundary, the first WL (1502), the BL (1504), the second WL (1506), and the BLB (1508) are arranged in the order as shown. For example, the first WL, BL, second WL, and BLB of FIG. 15 can correspond to the M0 tracks 370, 372, 374, and 376, respectively, as shown in FIGS. 4-5. In another example, the first WL, BL, second WL, and BLB of FIG. 15 can correspond to the M0 tracks 770, 772, 774, and 776, respectively, as shown in FIGS. 8-9. In some embodiments, these M0 tracks can extend along the X-direction. Further, the semiconductor device 400 or 800 can further include at least one M1 track 1510 extending in the Y-direction over the first WL, BL, BLB, and second WL, and coupled to the first WL and second WL through respective via structures 1520. Such an M1 track is disposed in a next bottommost (frontside) metallization layer, typically referred to as an M1 layer.

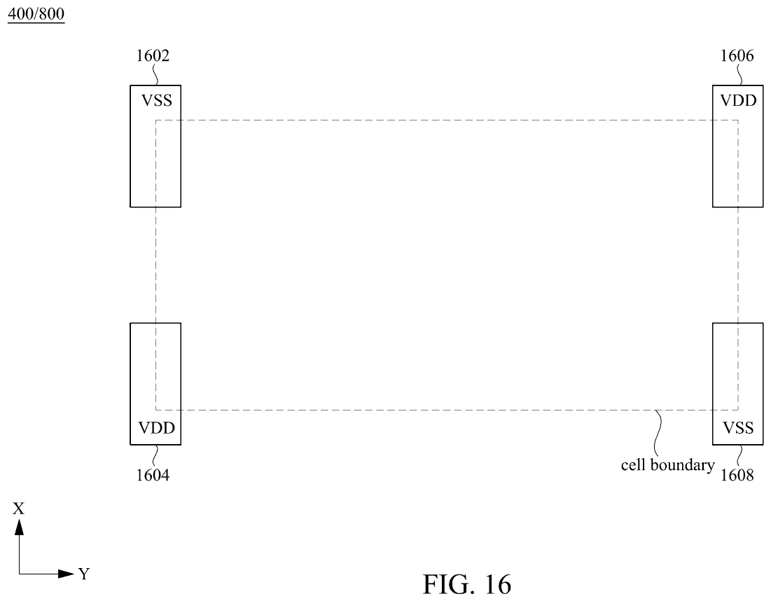

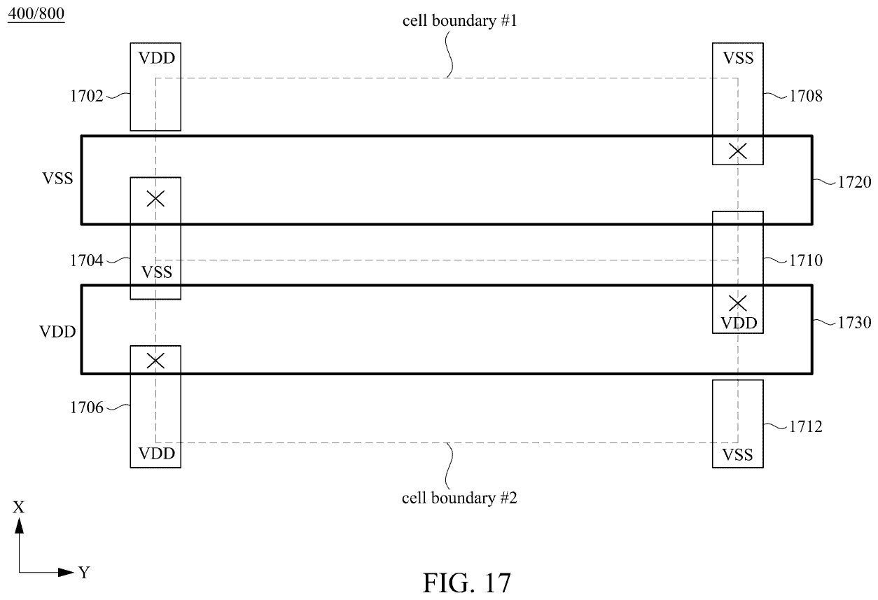

FIG. 16 and FIG. 17 respectively illustrate top (or bottom) views of the semiconductor device 400 (FIGS. 4-5) or 800 (FIGS. 8-9), in accordance with some embodiments. Each of the top/bottom views of FIGS. 16 and 17 includes a plural number of backside metal tracks disposed below one or more memory cells. It should be understood that the top views of FIGS. 16 and 17 are provided simply for illustrative purposes, and are not intended to limit the scope of the present disclosure.

The top/bottom view of FIG. 16 refers to an arrangement of plural BM0 tracks, 1602, 1604, 1606, and 1608, with respect to a corresponding cell boundary. The BM0 track 1602 is configured as a portion of a first power rail carrying VSS, the BM0 track 1604 is configured as a portion of a second power rail carrying VDD, the BM0 track 1606 is configured as a portion of a third power rail carrying VDD, and the BM0 track 1608 is configured as a fourth power rail carrying VSS. In some embodiments, the first power rail 1602 and the fourth power rail 1608 are disposed around one pair of corners of the cell boundary, respectively, and the second power rail 1604 and the third power rail 1606 are disposed around the other pair of corners of the cell boundary, respectively.

For example, the first power rail 1602, second power rail 1604, third power rail 1606, and fourth power rail 1608 of FIG. 16 can correspond to the BM0 tracks 280, 284, 286, and 282, respectively, as shown in FIGS. 4-5. In another example, the first power rail 1602, second power rail 1604, third power rail 1606, and fourth power rail 1608 of FIG. 16 can correspond to the BM0 tracks 680, 684, 686, and 682, respectively, as shown in FIGS. 8-9. In some embodiments, these BM0 tracks can extend along the X-direction. Further, the semiconductor device 400 or 800 can further include at least one BM1 track (not shown in FIG. 16) extending in the Y-direction and coupled to the first power rail 1602 and fourth power rail 1608 through respective via structures, and at least another BM1 track (not shown in FIG. 16) extending in the Y-direction and coupled to the second power rail 1604 and third power rail 1606 through respective via structures. Such BM1 tracks are disposed in a next bottommost (backside) metallization layer, typically referred to as a BM1 layer.

The top/bottom view of FIG. 17 refers to an arrangement of plural BM0 tracks, 1702, 1704, 1706, 1708, 1710, and 1712, with respect to two corresponding cell boundaries. The BM0 track 1702 is configured as a portion of a first power rail carrying VDD, the BM0 track 1704 is configured as a portion of a second power rail carrying VSS, the BM0 track 1706 is configured as a portion of a third power rail carrying VDD, the BM0 track 1708 is configured as a fourth power rail carrying VSS, the BM0 track 1710 is configured as a portion of a fifth power rail carrying VDD, and the BM0 track 1712 is configured as a sixth power rail carrying VSS. In some embodiments, the first power rail 1702 and the fifth power rail 1710 are disposed around one pair of corners of the first cell boundary, respectively, the second power rail 1704 and the fourth power rail 1708 are disposed around the other pair of corners of the first cell boundary, respectively, the second power rail 1704 and the sixth power rail 1712 are disposed around one pair of corners of the second cell boundary, respectively, and the third power rail 1706 and the fifth power rail 1710 are disposed around the other pair of corners of the second cell boundary, respectively. Further, the second power rail 1704 and the fifth power rail 1710 may be shared by the first and second cell boundaries, or by the corresponding memory cells.

For example, the first power rail 1702, second power rail 1704, fourth power rail 1708, and fifth power rail 1710 of FIG. 17 can correspond to the BM0 tracks 284, 280, 282, and 286, respectively, as shown in FIGS. 4-5. In another example, the first power rail 1702, second power rail 1704, fourth power rail 1708, and fifth power rail 1710 of FIG. 17 can correspond to the BM0 tracks 684, 680, 682, and 686, respectively, as shown in FIGS. 8-9. In some embodiments, these BM0 tracks can extend along the X-direction. Further, the semiconductor device 400 or 800 can further include at least one BM1 track 1720 extending in the Y-direction and coupled to the second power rail 1704 and fourth power rail 1708 through respective via structures, and at least another BM1 track 1730 extending in the Y-direction and coupled to the third power rail 1706 and fifth power rail 1710 through respective via structures. Such BM1 tracks are disposed in a next bottommost (backside) metallization layer, typically referred to as a BM1 layer.

FIG. 18 illustrates a flow chart of an example method 1800 for forming a memory cell configured in a CFET structure, according to some embodiments of the present disclosure. At least some of the operations (or steps) of the method 1800 can be used to form the memory cell 100 (FIG. 1) in the CFET structure, with an embedded power structure. For example, the CFET structure includes a number of p-type transistors disposed at the first level on the frontside of a substrate, a number of n-type transistors disposed at the second, upper level on the frontside of the substrate, and a power structure vertically extending through the first and second levels and laterally interposed between the p-type transistors and between the n-type transistors. In one aspect, the power structure can be formed as a one-piece wall structure. In another aspect, the power structure can be formed as a pair of via structures.

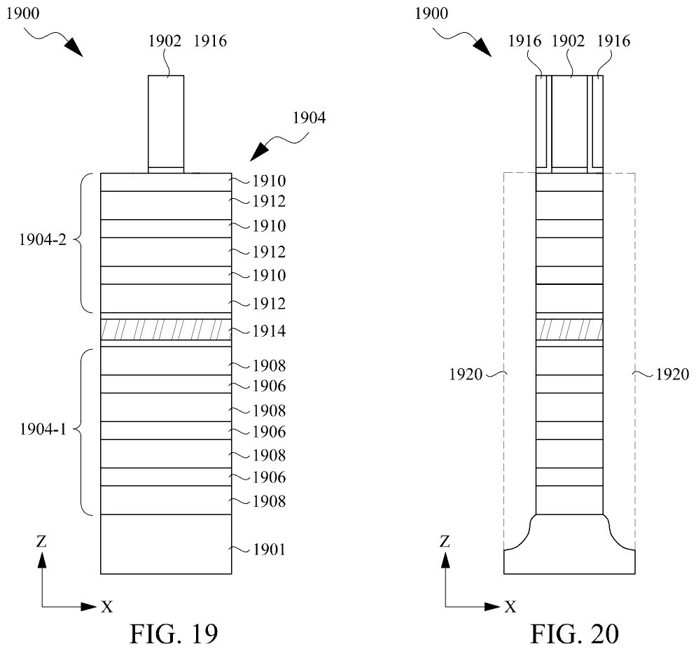

It should be appreciated that the method 1800 is merely an example, and is not intended to limit the present disclosure. Accordingly, it is understood that additional operations may be provided before, during, and after the method 1800 of FIG. 18, and that some other operations may only be briefly described herein. In some embodiments, operations of the method 1800 may be associated with cross-sectional views of a CFET structure 1900 (similar to the semiconductor device 400 of FIGS. 4-5, or the semiconductor device 800 of FIGS. 8-9) at various fabrication stages as shown in FIGS. 19, 20, 21, 22, 23, 24, 25, 26, 27, and 28, respectively, which will be discussed in further detail below.

As a brief overview, the method 1800 starts with operation 1802 of forming a number of dummy gate structures over a stack including a lower portion and an upper portion. The lower portion includes a number of first nanostructures and a number of second nanostructures alternately stacked on top of one another, and the upper portion includes a number of third nanostructures and a number of fourth nanostructures alternately stacked on top of one another. The first and third nanostructures may be formed of a first semiconductor material, and the second and fourth nanostructures may be formed of a second semiconductor material. Further, the lower portion and the upper portion may be separated from each other with a fifth nanostructure formed of a third semiconductor material. The method 1800 continues to operation 1804 of etching the stack to form source/drain recesses. The 1800 continues to operation 1806 of laterally recessing the second nanostructures and the fourth nanostructures. The method 1800 continues to operation 1808 of forming a number of inner spacers. The method 1800 continues to operation 1810 of selectively removing the fifth nanostructure. The method 1800 continues to operation 1812 of forming a dielectric layer between the lower portion and the upper portion. The method 1800 continues to operation 1814 of forming a number of p-type epitaxial structures in the lower portion and a number of n-type epitaxial structures in the upper portion. The method 1800 continues to operation 1816 of forming a first active gate structure in the lower portion and a second active gate structure in the upper portion. The method 1800 continues to operation 1818 of forming a power structure. The method 1800 continues to operation 1820 of forming a number of contact structures.

Corresponding to operation 1802 of FIG. 18, FIG. 19 is a cross-sectional view of the CFET structure 1900 including a number of dummy gate structures 1902 over a stack 1904, at one of the various stages of fabrication. The cross-sectional view of FIG. 19 is cut along the lengthwise direction of an active region of the CFET structure 1900 (e.g., the X-direction illustrated above).

In some embodiments, the stack 1904 may be formed over a semiconductor substrate 1901, followed by the dummy gate structure 1902 formed over the stack 1904. The stack 1904 can extend along the X-direction, and the dummy gate structure 1902 can extend along the Y-direction to straddle or otherwise traverse the stack 1904. The stack 1904 includes a lower portion 1904-1 and an upper portion 1904-2, which can correspond to the first level and the second level on the frontside of the substrate (e.g., FIGS. 4-5, 8-9), respectively. The lower portion 1904-1 includes a number of first nanostructures 1906 and a number of second nanostructures 1908 alternately stacked on top of one another, and the upper portion 1904-2 includes a number of third nanostructures 1910 and a number of fourth nanostructures 1912 alternately stacked on top of one another.

The substrate 1901, the first nanostructures 1906, and the third nanostructures 1910 may be formed of a first semiconductor material, e.g., silicon (Si), while the second nanostructures 1908 and the fourth nanostructures 1912 may be formed of a second semiconductor material, e.g., silicon germanium (Si₁₋ₓGeₓ). Further, the lower portion 1904-1 and the upper portion 1904-2 are separated from each other with a fifth nanostructure 1914 formed of a third semiconductor material, e.g., silicon germanium (Si_{1-y}Ge_{y}). In some embodiments, the molar ratio “x” of the second semiconductor material may be less than 0.5, and the molar ratio “y”of the third semiconductor material may be higher than 0.5.

The nanostructures 1906 to 1912 can be epitaxially grown from the semiconductor substrate 1901. For example, each of the nanostructures 1906 to 1912 may be grown by a molecular beam epitaxy (MBE) process, a chemical vapor deposition (CVD) process such as a metal organic CVD (MOCVD) process, and/or other suitable epitaxial growth processes. Upon growing the nanostructures 1906 to 1912 on the substrate 1901 as a blanket stack, the blanket stack may be patterned to form the stack 1904 shown in FIG. 19 (e.g., having a lengthwise direction in the X-direction and a relatively narrow width in the Y-direction). After the stack 1904 is formed, the dummy gate structure 1902, including a dummy gate dielectric (e.g., silicon oxide) and a dummy gate material (e.g., polysilicon), is formed to straddle the stack 1904.

Corresponding to operation 1804 of FIG. 18, FIG. 20 is a cross-sectional view of the CFET structure 1900 in which source/drain recesses 1920 are formed, at one of the various stages of fabrication. The cross-sectional view of FIG. 20 is cut along the lengthwise direction of an active region of the CFET structure 1900 (e.g., the X-direction illustrated above).

To form the source/drain recesses 1920, a pair of gate spacers 1916 may be formed on opposite sidewalls of the dummy gate structure 1902. Next, with the dummy gate structure 1902 and the gate spacers 1916 serving as a mask, the stack 1904 is again patterned to form the source/drain recesses 1920 using an anisotropic etching process. Such an anisotropic etching process can include reactive ion etch (RIE), neutral beam etch (NBE), the like, or combinations thereof.

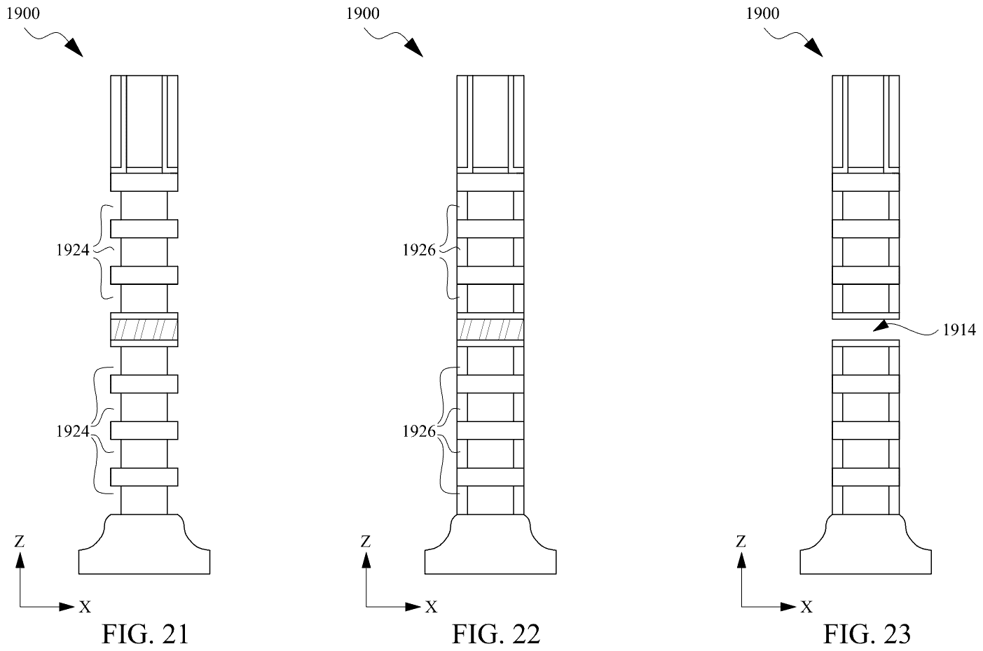

Corresponding to operation 1806 of FIG. 18, FIG. 21 is a cross-sectional view of the CFET structure 1900 in which the second nanostructures 1908 and the fourth nanostructures 1912 are laterally recessed, at one of the various stages of fabrication. The cross-sectional view of FIG. 21 is cut along the lengthwise direction of an active region of the CFET structure 1900 (e.g., the X-direction illustrated above).

As shown, respective end portions of each of the second nanostructures 1908 and the fourth nanostructures 1912 (formed of Si₁₋ₓGeₓ) are removed (e.g., etched) using a “pull-back” process to pull each of the nanostructures 1908 and 1912 back by a pull-back distance. For example, the pull-back process may include a hydrogen chloride (HCl) gas isotropic etching process, which etches SiGe with the lower Ge composition (e.g., Si₁₋ₓGeₓ) without attacking Si or SiGe with the higher Ge composition (e.g., Si_{1-y}Ge_{y}). As such, the nanostructures 1906 (Si), 1910 (Si), and 1914 (Si_{1-y}Ge_{y}) may remain substantially intact during this process, and a number of recess 1924, each inwardly extending from the source/drain recess 1920, can be formed.

Corresponding to operation 1808 of FIG. 18, FIG. 22 is a cross-sectional view of the CFET structure 1900 including a number of inner spacers 1926, at one of the various stages of fabrication. The cross-sectional view of FIG. 22 is cut along the lengthwise direction of an active region of the CFET structure 1900 (e.g., the X-direction illustrated above).

The inner spacers 1926 can be formed by filling the recesses 1924 with a dielectric material. For example, the inner spacers 1926 can be deposited using, e.g., a conformal deposition process and subsequent isotropic or anisotropic etch back to remove excess spacer material on the sidewalls of the stack 1904. The dielectric material, used to form the inner spacer 1926, includes silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating gate sidewall spacers of transistors.

Corresponding to operation 1810 of FIG. 18, FIG. 23 is a cross-sectional view of the CFET structure 1900 in which the fifth nanostructure 1914 is removed, at one of the various stages of fabrication. The cross-sectional view of FIG. 23 is cut along the lengthwise direction of an active region of the CFET structure 1900 (e.g., the X-direction illustrated above).

After forming the inner spacers 1926, the fifth nanostructure 1914 can be selectively removed using an isotropic etching process that etches Si_{1-y}Ge_{y} without attacking Si. As such, the first nanostructures 1906 (Si) and third nanostructures 1910 (Si) can remain substantially intact, the fifth nanostructure 1914 (Si_{1-y}—Ge_{y}) can be completely removed, and the remaining portions of the second nanostructures 1908 (Si₁₋ₓGeₓ) and fourth nanostructures 1912 (Si₁₋ₓGeₓ) can remain with the protection of the inner spacers 1926.

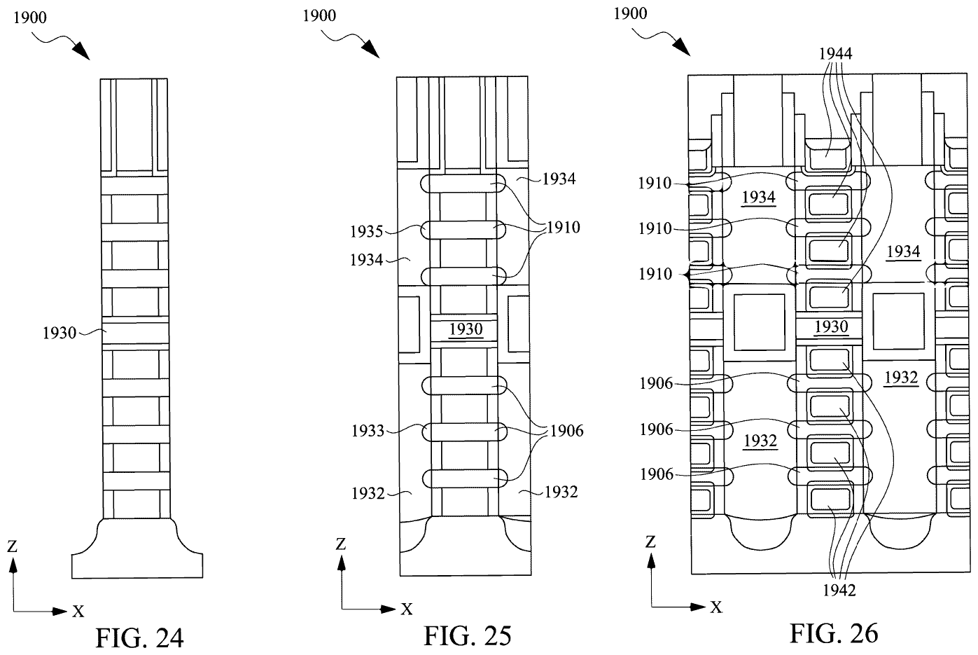

Corresponding to operation 1812 of FIG. 18, FIG. 24 is a cross-sectional view of the CFET structure 1900 including a dielectric layer 1930, at one of the various stages of fabrication. The cross-sectional view of FIG. 24 is cut along the lengthwise direction of an active region of the CFET structure 1900 (e.g., the X-direction illustrated above).

After the fifth nanostructure 1914 is removed, a space is formed between the lower portion 1904-1 and the upper portion 1904-2. The dielectric layer 1930 can be formed by filling the space with a dielectric material. The dielectric material, used to form the dielectric layer 1930, includes silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating structure for transistors.

Corresponding to operation 1814 of FIG. 18, FIG. 25 is a cross-sectional view of the CFET structure 1900 including a number of first epitaxial structures 1932 and a number of second epitaxial structures 1934, at one of the various stages of fabrication. The cross-sectional view of FIG. 25 is cut along the lengthwise direction of an active region of the CFET structure 1900 (e.g., the X-direction illustrated above).

As shown, a pair of the first epitaxial structure 1932 are coupled to ends of each of the first nanostructures 1906, respectively; and a pair of the second epitaxial structure 1934 are coupled to ends of each of the third nanostructures 1910, respectively. The first epitaxial structures 1932 can be formed through a first epitaxial growth process, followed by a second epitaxial growth process for forming the second epitaxial structures 1934. Further, between the first epitaxial growth process and the second epitaxial growth process, one or more dielectric layers 1936 can be formed to electrically isolate the first epitaxial structures 1932 and the second epitaxial structures 1934. Each of the first epitaxial growth process and the second epitaxial growth process can include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epitaxial processes. Specifically, the first epitaxial structures 1932 can be grown from the first nanostructures 1906, and the second epitaxial structures 1934 can be grown from the third nanostructures 1910.

The first epitaxial structures 1932 and the second epitaxial structures 1934 may each include silicon germanium (SiGe), indium arsenide (InAs), indium gallium arsenide (InGaAs), indium antimonide (InSb), germanium arsenide (GaAs), germanium antimonide (GaSb), indium aluminum phosphide (InAlP), indium phosphide (InP), any other suitable material, or combinations thereof. Further, in-situ doping (ISD) may be applied during the formation of each of the first epitaxial structures 1932 and the second epitaxial structures 1934. For example, the first epitaxial structures 1932 can be doped by implanting p-type dopants, e.g., boron (B), etc., into them; and the second epitaxial structures 1934 can be doped by implanting n-type dopants, e.g., arsenic (As), phosphorous (P), etc., into them. In some embodiments, the first epitaxial structure 1932 can be coupled to each of the first nanostructures 1906 through a lightly doped region 1933 (e.g., SiGeB); and the second epitaxial structure 1934 can be coupled to each of the third nanostructures 1910 through a lightly doped region 1935 (e.g., SiP).

Corresponding to operation 1816 of FIG. 18, FIG. 26 is a cross-sectional view of the CFET structure 1900 including a first active gate structure 1942 and a second active gate structure 1944, at one of the various stages of fabrication. The cross-sectional view of FIG. 26 is cut along the lengthwise direction of an active region of the CFET structure 1900 (e.g., the X-direction illustrated above).

As shown, the first active gate structure 1942 wraps around each of the first nanostructures 1906; and the second active gate structure 1944 wraps around each of the third nanostructures 1910. To form the first active gate structure 1942 and second active gate structure 1944, the dummy gate structure 1902, the remaining portions of the second nanostructures 1908, and the remaining portions of the fourth nanostructures 1912 are removed. As such, a first gate trench, exposing each of the first nanostructures 1906, may be formed in the lower portion 1904-1 (e.g., the first level); and a second gate trench, exposing each of the third nanostructures 1910, may be formed in the upper portion 1904-2 (e.g., the second level). Next, the first active gate structure 1942 can be formed in the first gate trench to wrap around each of the first nanostructures 1906; and the second active gate structure 1944 can be formed in the second gate trench to wrap around each of the third nanostructures 1910.

In some embodiments, the first active gate structure 1942 can include a first gate dielectric and a first gate metal; and the second active gate structure 1944 can include a second gate dielectric and a second gate metal. The first/second gate dielectric may be formed of different high-k dielectric materials or a similar high-k dielectric material. Example high-k dielectric materials include a metal oxide or a silicate of Hf, Al, Zr, La, Mg, Ba, Ti, Pb, and combinations thereof. The first/second gate dielectric may include a stack of multiple high-k dielectric materials. The first gate metal may include one or more p-type work function metals, which may include TiN, TaN, Ru, Mo, Al, WN, ZrSi₂, MoSi₂, TaSi₂, NiSi₂, WN, other suitable p-type work function materials, or combinations thereof; and the second gate metal may include one or more n-type work function metals, may include Ti, Ag, TaAl, TaAlC, TiAlN, TaC, TaCN, TaSiN, Mn, Zr, other suitable n-type work function materials, or combinations thereof.

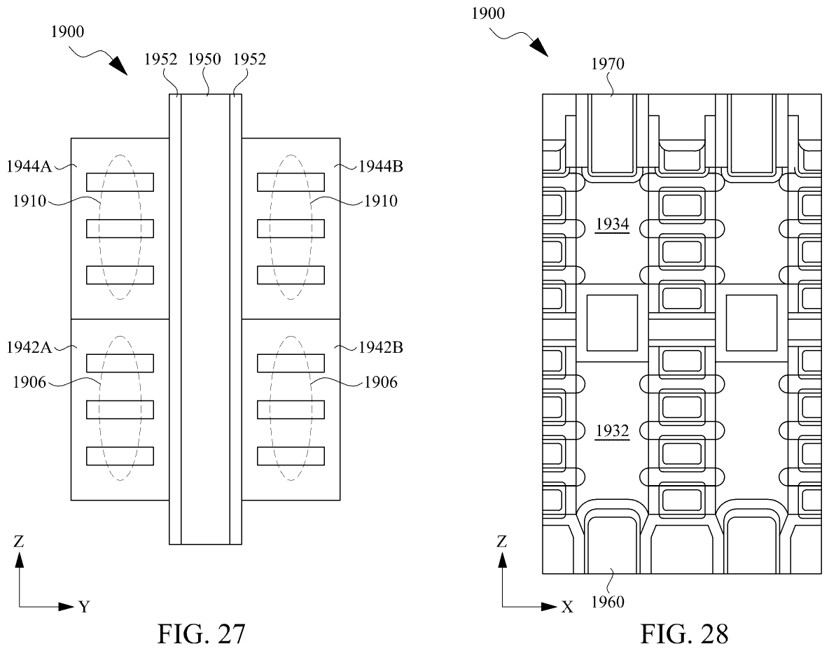

Corresponding to operation 1818 of FIG. 18, FIG. 27 is a cross-sectional view of the CFET structure 1900 including a power structure 1950, at one of the various stages of fabrication. The cross-sectional view of FIG. 27 is cut along the lengthwise direction of a gate structure of the CFET structure 1900 (e.g., the Y-direction illustrated above).

As shown, the power structure 1950 is configured to separate the first active gate structure 1942 into gate sections 1942A and 1942B, and separate the second active gate structure 1944 into gate sections 1944A and 1944B. The gate sections 1942A and 1942B are separated from each other along the Y-direction, and the gate sections 1944A and 1944B are separated from each other along the Y-direction. Further, the power structure 1950 is electrically isolated from the separated gate sections, e.g., gate sections 1942A and 1942B, gate sections 1944A and 1944B, with a dielectric structure 1952.

In some embodiments, the power structure 1950 can correspond to the wall structure 244/344, and the dielectric structure 1952 can correspond to the dielectric structure 242/342 (FIGS. 2-5). As such, the gate section 1942A and 1942B can correspond to the gate sections 230A and 230B or the gate sections 240A and 240B, respectively, and the gate section 1944A and 1944B can correspond to the gate sections 330A and 330B or the gate sections 340A and 340B, respectively. In some other embodiments, the power structure 1950 can correspond to the via structure 644A/744A or 644B/744B, and the dielectric structure 1952 can correspond to the dielectric structure 642/742 (FIGS. 6-9). As such, the gate section 1942A and 1942B can correspond to the gate sections 630A and 630B or the gate sections 640A and 640B, respectively, and the gate section 1944A and 1944B can correspond to the gate sections 730A and 730B or the gate sections 740A and 740B, respectively.

To form the power structure 1950, a middle portion of the first active gate structure 1942 and the second gate structure 1944, following a cut pattern discussed above (e.g., 242/342, 642/742), may be removed. For example, this middle portion of the first and second active gate structures is removed through at least one anisotropic etching process, thereby forming a vertical trench extending from the first level to the second level. Next, a dielectric material (e.g., silicon nitride) can be deposited to fill up the vertical trench, followed by deposition of a metal material (e.g., copper) to form the power structure 1950. The one-piece wall structure (e.g., 244/344) can be self-aligned with the vertical trench (i.e., no further lithography process). The duet of via structures (e.g., 644A/744A and 644B/744B) may be formed through another lithography process. For example, after the deposition of the dielectric material into the vertical trench, a lithography process can be performed to form a pair of vertical trenches extending through the dielectric material, followed by deposition of the metal material.

Upon the power structure 1950 being formed, at least two p-type transistors can be formed at the first level and on the opposite sides of the power structure 1950, respectively, and at least two n-type transistors can be formed at the second level and on the opposite sides of the power structure 1950, respectively. The p-type transistor can be operatively formed based on the first nanostructures 1906, the gate section 1942A or 1942B, and the pair of first epitaxial structures 1932. The n-type transistor can be operatively formed based on the third nanostructures 1910, the gate section 1944A or 1944B, and the pair of second epitaxial structures 1934.

Corresponding to operation 1818 of FIG. 18, FIG. 28 is a cross-sectional view of the CFET structure 1900 including first contact structures 1960 and second contact structures 1970, at one of the various stages of fabrication. The cross-sectional view of FIG. 28 is cut along the lengthwise direction of an active region of the CFET structure 1900 (e.g., the X-direction illustrated above).

As shown, the first contact structure 1960 is coupled to a corresponding one of the first epitaxial structures 1932; and the second contact structure 1970 is coupled to a corresponding one of the second epitaxial structures 1934. For example, the first contact structure 1960 may be formed below the first epitaxial structure 1932; and the second contact structure 1970 may be formed above the second epitaxial structure 1934. For another example, the first contact structure 1960 may wrap around the first epitaxial structure 1932; and the second contact structure 1970 may wrap around the second epitaxial structure 1934. In some embodiments, the first contact structure 1960 and the second contact structure 1970 may each be configured as an MD, as described above, which can include titanium, aluminum, nickel, tungsten, tantalum, or other suitable metal materials.

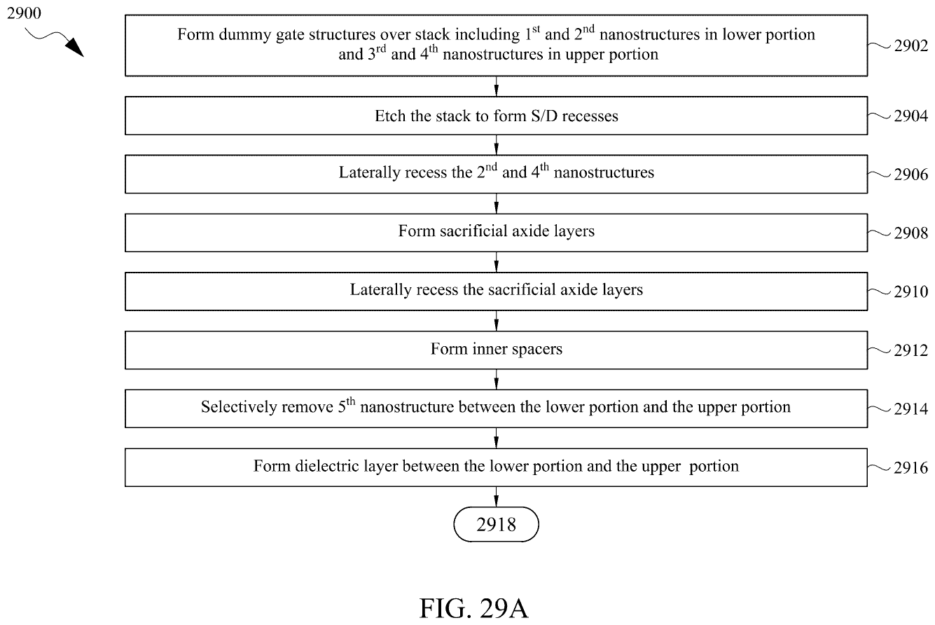

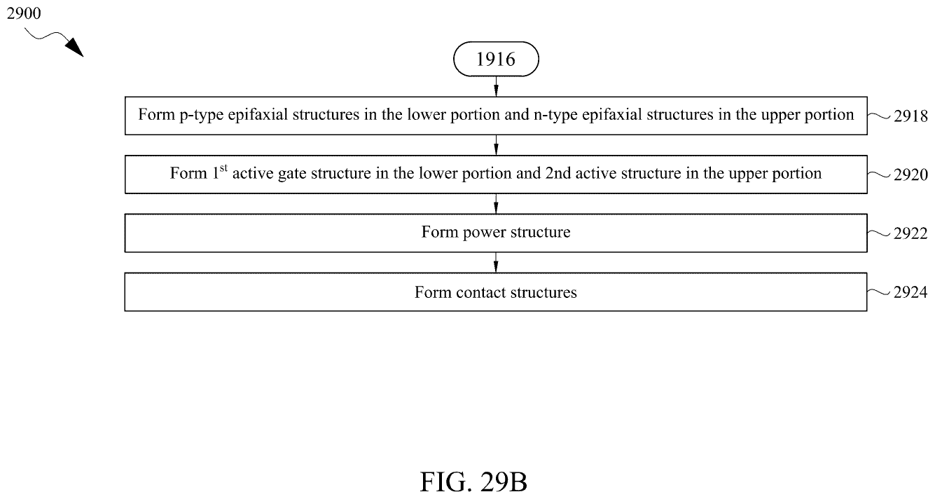

FIG. 29 illustrates a flow chart of another example method 2900 for forming a memory cell configured in a CFET structure, according to some embodiments of the present disclosure. At least some of the operations (or steps) of the method 2900 can be used to form the memory cell 100 (FIG. 1) in the CFET structure, with an embedded power structure. For example, the CFET structure includes a number of p-type transistors disposed at the first level on the frontside of a substrate, a number of n-type transistors disposed at the second, upper level on the frontside of the substrate, and a power structure vertically extending through the first and second levels and laterally interposed between the p-type transistors and between the n-type transistors. In one aspect, the power structure can be formed as a one-piece wall structure. In another aspect, the power structure can be formed as a pair of via structures.

It should be appreciated that the method 2900 is merely an example, and is not intended to limit the present disclosure. Accordingly, it is understood that additional operations may be provided before, during, and after the method 2900 of FIG. 29, and that some other operations may only be briefly described herein. In some embodiments, operations of the method 2900 may be associated with cross-sectional views of a CFET structure 3000 (similar to the semiconductor device 400 of FIGS. 4-5, or the semiconductor device 800 of FIGS. 8-9) at various fabrication stages as shown in FIGS. 31, 32, 33, 34, 35, 36, 37, 38, 39, 40, and 41, respectively, which will be discussed in further detail below.

As a brief overview, the method 2900 starts with operation 2902 of forming a number of dummy gate structures over a stack including a lower portion and an upper portion. The lower portion includes a number of first nanostructures and a number of second nanostructures alternately stacked on top of one another, and the upper portion includes a number of third nanostructures and a number of fourth nanostructures alternately stacked on top of one another. The first and third nanostructures may be formed of a first semiconductor material, and the second and fourth nanostructures may be formed of a second semiconductor material. Further, the lower portion and the upper portion may be separated from each other with a fifth nanostructure formed of a third semiconductor material. The method 2900 continues to operation 2904 of etching the stack to form source/drain recesses. The 2900 continues to operation 2906 of removing the second nanostructures and the fourth nanostructures. The method 2900 continues to operation 2908 of forming a plural number of sacrificial oxide layers each interposed between adjacent ones of the first nanostructures or between adjacent ones of the third nanostructures. The method 2900 continues to operation 2910 of laterally recessing the sacrificial oxide layers. The method 2900 continues to operation 2912 of forming a number of inner spacers. The method 2900 continues to operation 2914 of selectively removing the fifth nanostructure. The method 2900 continues to operation 2916 of forming a dielectric layer between the lower portion and the upper portion. The method 2900 continues to operation 2918 of forming a number of p-type epitaxial structures in the lower portion and a number of n-type epitaxial structures in the upper portion. The method 2900 continues to operation 2920 of forming a first active gate structure in the lower portion and a second active gate structure in the upper portion. The method 2900 continues to operation 2922 of forming a power structure. The method 2900 continues to operation 2924 of forming a number of contact structures.

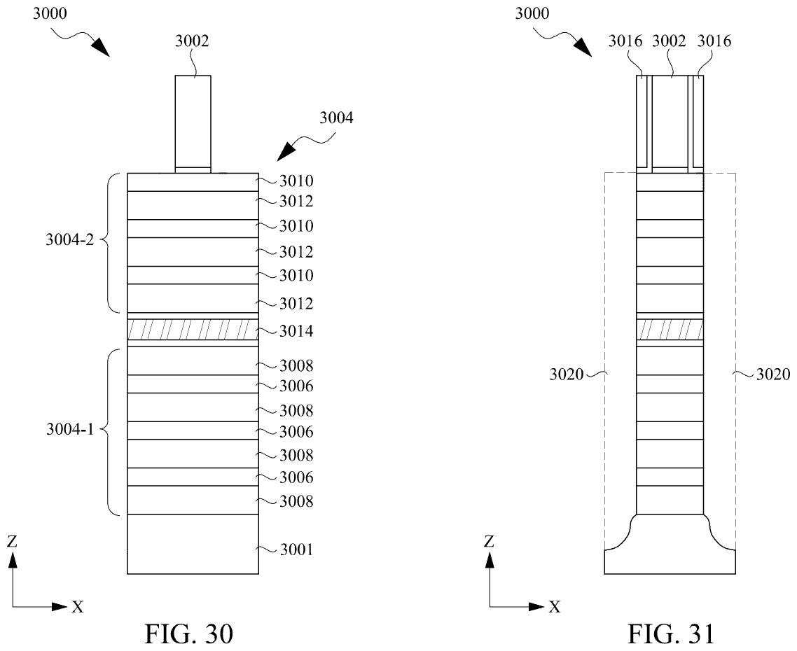

Corresponding to operation 2902 of FIG. 29, FIG. 30 is a cross-sectional view of the CFET structure 3000 including a number of dummy gate structures 3002 over a stack 3004, at one of the various stages of fabrication. The cross-sectional view of FIG. 30 is cut along the lengthwise direction of an active region of the CFET structure 3000 (e.g., the X-direction illustrated above).

In some embodiments, the stack 3004 may be formed over a semiconductor substrate 3001, followed by the dummy gate structure 3002 formed over the stack 3004. The stack 3004 can extend along the X-direction, and the dummy gate structure 3002 can extend along the Y-direction to straddle or otherwise traverse the stack 3004. The stack 3004 includes a lower portion 3004-1 and an upper portion 3004-2, which can correspond to the first level and the second level on the frontside of the substrate (e.g., FIGS. 4-5, 8-9), respectively. The lower portion 3004-1 includes a number of first nanostructures 3006 and a number of second nanostructures 3008 alternately stacked on top of one another, and the upper portion 3004-2 includes a number of third nanostructures 3010 and a number of fourth nanostructures 3012 alternately stacked on top of one another.

The substrate 3001, the first nanostructures 3006, and the third nanostructures 3010 may be formed of a first semiconductor material, e.g., silicon (Si), while the second nanostructures 3008 and the fourth nanostructures 3012 may be formed of a second semiconductor material, e.g., silicon germanium (Si₁₋ₓGeₓ). Further, the lower portion 3004-1 and the upper portion 3004-2 are separated from each other with a fifth nanostructure 3014 formed of a third semiconductor material, e.g., silicon germanium (Si_{1-y}—Ge_{y}). In some embodiments, the molar ratio “x” of the second semiconductor material may be less than 0.5, and the molar ratio “y”of the third semiconductor material may be higher than 0.5.

The nanostructures 3006 to 3012 can be epitaxially grown from the semiconductor substrate 3001. For example, each of the nanostructures 3006 to 3012 may be grown by a molecular beam epitaxy (MBE) process, a chemical vapor deposition (CVD) process such as a metal organic CVD (MOCVD) process, and/or other suitable epitaxial growth processes. Upon growing the nanostructures 3006 to 3012 on the substrate 3001 as a blanket stack, the blanket stack may be patterned to form the stack 3004 shown in FIG. 30 (e.g., having a lengthwise direction in the X-direction and a relatively narrow width in the Y-direction). After the stack 3004 is formed, the dummy gate structure 3002, including a dummy gate dielectric (e.g., silicon oxide) and a dummy gate material (e.g., polysilicon), is formed to straddle the stack 3004.

Corresponding to operation 2904 of FIG. 29, FIG. 31 is a cross-sectional view of the CFET structure 3000 in which source/drain recesses 3020 are formed, at one of the various stages of fabrication. The cross-sectional view of FIG. 31 is cut along the lengthwise direction of an active region of the CFET structure 3000 (e.g., the X-direction illustrated above).

To form the source/drain recesses 3020, a pair of gate spacers 3016 may be formed on opposite sidewalls of the dummy gate structure 3002. Next, with the dummy gate structure 3002 and the gate spacers 3016 serving as a mask, the stack 3004 is again patterned to form the source/drain recesses 3020 using an anisotropic etching process. Such an anisotropic etching process can include reactive ion etch (RIE), neutral beam etch (NBE), the like, or combinations thereof.

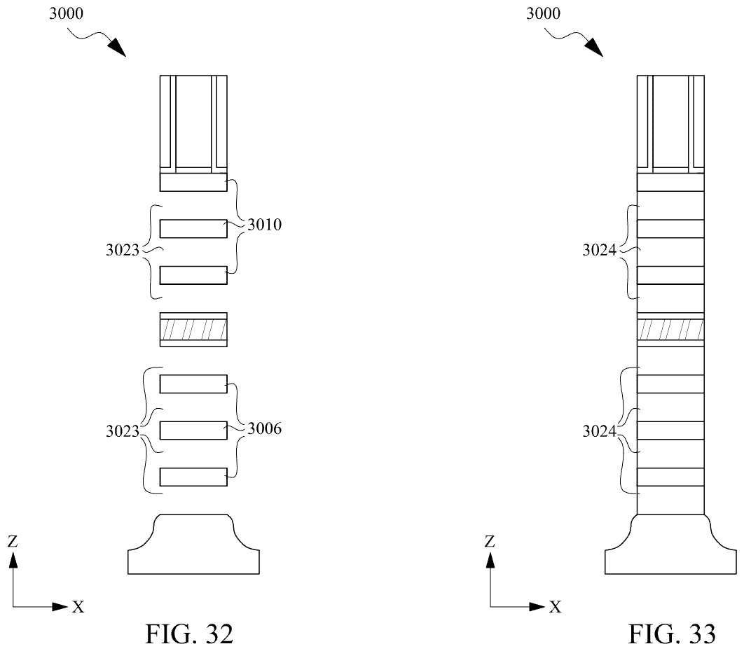

Corresponding to operation 2906 of FIG. 29, FIG. 32 is a cross-sectional view of the CFET structure 3000 in which the second nanostructures 3008 and the fourth nanostructures 3012 are removed, at one of the various stages of fabrication. The cross-sectional view of FIG. 32 is cut along the lengthwise direction of an active region of the CFET structure 3000 (e.g., the X-direction illustrated above).

In some embodiments, the second nanostructures 3008 and the fourth nanostructures 3012 may be selectively removed (e.g. etched), with the first nanostructures 3006, the third nanostructures 3010, and the fifth nanostructure 3014 remaining substantially intact. The second nanostructures 3008 and the fourth nanostructures 3012 may be completely removed using a hydrogen chloride (HCl) gas isotropic etching process, which etches SiGe with the lower Ge composition (e.g., Si₁₋ₓGeₓ) without attacking Si or SiGe with the higher Ge composition (e.g., Si_{1-y}Ge_{y}). As such, a plural number of spaces 3023 can be formed. Each of the spaces 3023 can be vertically interposed between the substrate 3001 and a bottommost one of the first nanostructures 3006, between the adjacent ones of the first nanostructures 3006, between a topmost one of the first nanostructures 3006 and the fifth nanostructure 3014, between the fifth nanostructure 3014 and a bottommost one of the third nanostructures 3010, or between the adjacent ones of the third nanostructures 3010, as shown in FIG. 32.

Corresponding to operation 2908 of FIG. 29, FIG. 33 is a cross-sectional view of the CFET structure 3000 including a plural number of sacrificial oxide layers 3024, at one of the various stages of fabrication. The cross-sectional view of FIG. 33 is cut along the lengthwise direction of an active region of the CFET structure 3000 (e.g., the X-direction illustrated above).

As shown, the sacrificial oxide layers 3024 are formed at least in the spaces 3023, respectively. In some embodiments, the sacrificial oxide layers 3024 may be formed using, e.g., a conformal deposition process to deposit an oxide material and one or more subsequent isotropic or anisotropic etching processes to remove the excessive oxide material on the sidewalls of the stack 3004. As such, the sacrificial oxide layers 3024 can each be vertically interposed between the substrate 3001 and the bottommost first nanostructures 3006, between the adjacent first nanostructures 3006, between the topmost first nanostructure 3006 and the fifth nanostructure 3014, between the fifth nanostructure 3014 and the bottommost third nanostructure 3010, or between the adjacent third nanostructures 3010, as shown in FIG. 33.

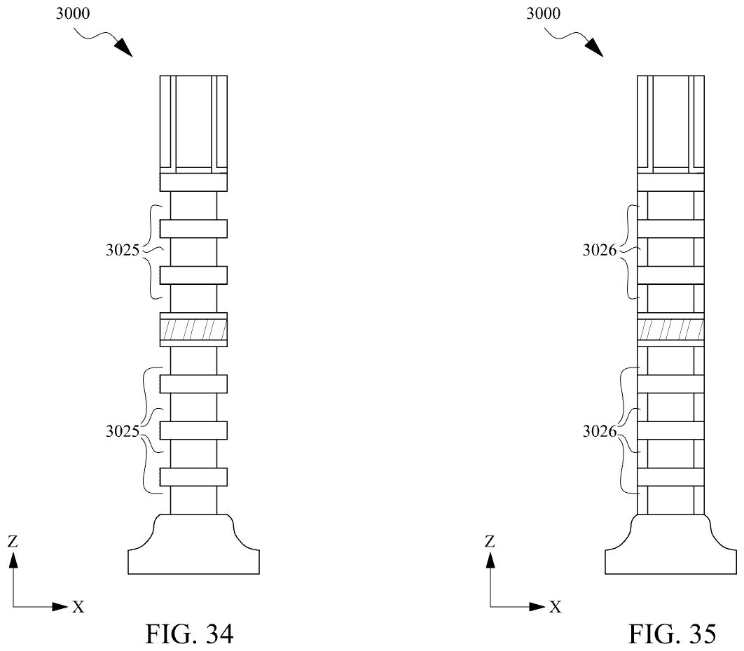

Corresponding to operation 2910 of FIG. 29, FIG. 34 is a cross-sectional view of the CFET structure 3000 in which the sacrificial oxide layers 3024 are laterally recessed, at one of the various stages of fabrication. The cross-sectional view of FIG. 34 is cut along the lengthwise direction of an active region of the CFET structure 3000 (e.g., the X-direction illustrated above).

As shown, respective end portions of each of the sacrificial oxide layers 3024 are removed (e.g., etched) using a “pull-back” process to pull each of the sacrificial oxide layers 3024 back by a pull-back distance. For example, the pull-back process may include a hydrofluoric acid (HF) gas isotropic etching process, which etches silicon oxide without attacking Si or SiGe with the higher Ge composition (e.g., Si_{1-y}Ge_{y}). As such, the nanostructures 3006 (Si), 3010 (Si), and 3014 (Si_{1-y}Ge_{y}) may remain substantially intact during this process, and a number of recess 3025, each inwardly extending from the source/drain recess 3020, can be formed.

Corresponding to operation 2912 of FIG. 29, FIG. 35 is a cross-sectional view of the CFET structure 3000 including a number of inner spacers 3026, at one of the various stages of fabrication. The cross-sectional view of FIG. 35 is cut along the lengthwise direction of an active region of the CFET structure 3000 (e.g., the X-direction illustrated above).

The inner spacers 3026 can be formed by filling the recesses 3025 with a dielectric material. For example, the inner spacers 3026 can be deposited using, e.g., a conformal deposition process and subsequent isotropic or anisotropic etch back to remove excess spacer material on the sidewalls of the stack 3004. The dielectric material, used to form the inner spacer 3026, includes silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating gate sidewall spacers of transistors.

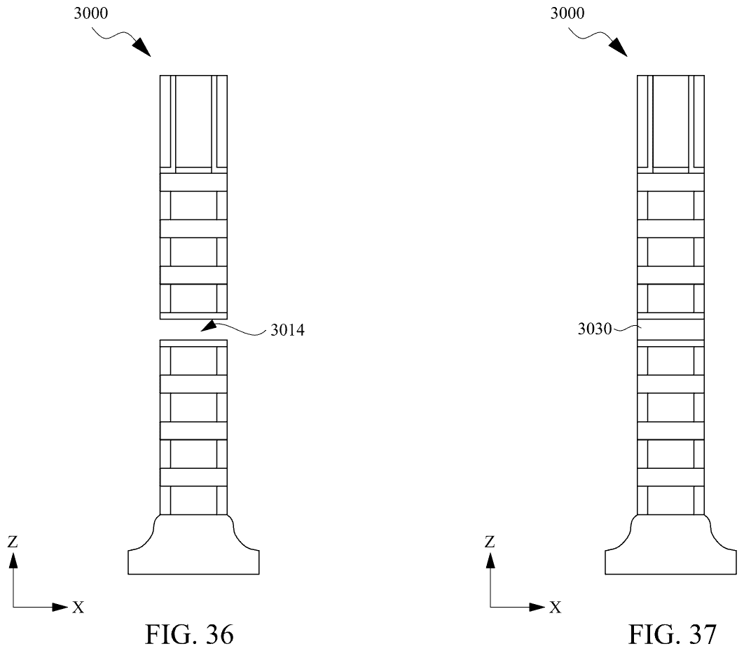

Corresponding to operation 2914 of FIG. 29, FIG. 36 is a cross-sectional view of the CFET structure 3000 in which the fifth nanostructure 3014 is removed, at one of the various stages of fabrication. The cross-sectional view of FIG. 36 is cut along the lengthwise direction of an active region of the CFET structure 3000 (e.g., the X-direction illustrated above).

After forming the inner spacers 3026, the fifth nanostructure 3014 can be selectively removed using an isotropic etching process that etches Si_{1-y}Ge_{y} without attacking Si. As such, the first nanostructures 3006 (Si) and third nanostructures 3010 (Si) can remain substantially intact, the fifth nanostructure 3014 (Si_{1-y}Ge_{y}) can be completely removed, and the remaining portions of the sacrificial oxide layers 3024 can remain with the protection of the inner spacers 3026.

Corresponding to operation 2916 of FIG. 29, FIG. 37 is a cross-sectional view of the CFET structure 3000 including a dielectric layer 3030, at one of the various stages of fabrication. The cross-sectional view of FIG. 37 is cut along the lengthwise direction of an active region of the CFET structure 3000 (e.g., the X-direction illustrated above).

After the fifth nanostructure 3014 is removed, a space is formed between the lower portion 3004-1 and the upper portion 3004-2. The dielectric layer 3030 can be formed by filling the space with a dielectric material. The dielectric material, used to form the dielectric layer 3030, includes silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating structure for transistors.

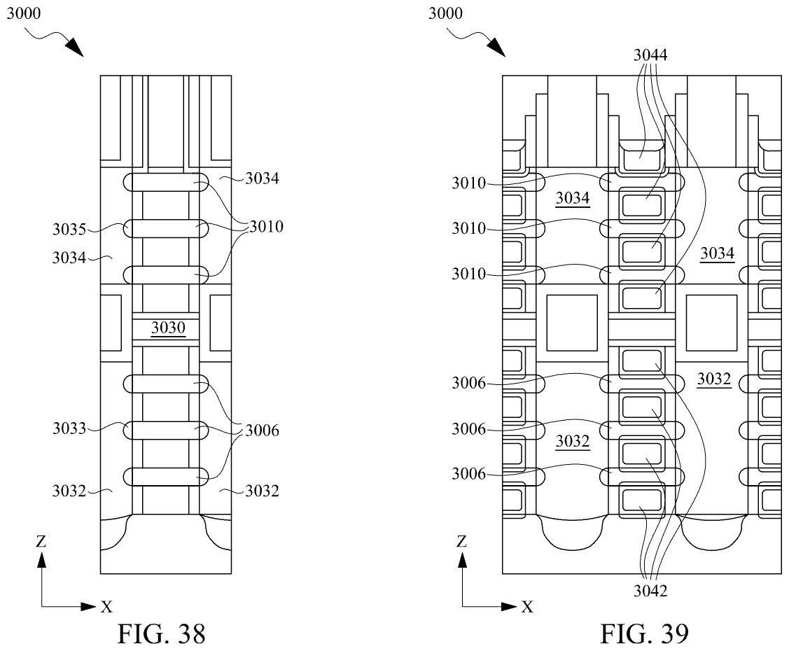

Corresponding to operation 2918 of FIG. 35, FIG. 38 is a cross-sectional view of the CFET structure 3000 including a number of first epitaxial structures 3032 and a number of second epitaxial structures 3034, at one of the various stages of fabrication. The cross-sectional view of FIG. 38 is cut along the lengthwise direction of an active region of the CFET structure 3000 (e.g., the X-direction illustrated above).

As shown, a pair of the first epitaxial structure 3032 are coupled to ends of each of the first nanostructures 3006, respectively; and a pair of the second epitaxial structure 3034 are coupled to ends of each of the third nanostructures 3010, respectively. The first epitaxial structures 3032 can be formed through a first epitaxial growth process, followed by a second epitaxial growth process for forming the second epitaxial structures 3034. Further, between the first epitaxial growth process and the second epitaxial growth process, one or more dielectric layers 3030 can be formed to electrically isolate the first epitaxial structures 3032 and the second epitaxial structures 3034. Each of the first epitaxial growth process and the second epitaxial growth process can include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epitaxial processes. Specifically, the first epitaxial structures 3032 can be grown from the first nanostructures 3006, and the second epitaxial structures 3034 can be grown from the third nanostructures 3010.

The first epitaxial structures 3032 and the second epitaxial structures 3034 may each include silicon germanium (SiGe), indium arsenide (InAs), indium gallium arsenide (InGaAs), indium antimonide (InSb), germanium arsenide (GaAs), germanium antimonide (GaSb), indium aluminum phosphide (InAlP), indium phosphide (InP), any other suitable material, or combinations thereof. Further, in-situ doping (ISD) may be applied during the formation of each of the first epitaxial structures 3032 and the second epitaxial structures 3034. For example, the first epitaxial structures 3032 can be doped by implanting p-type dopants, e.g., boron (B), etc., into them; and the second epitaxial structures 3034 can be doped by implanting n-type dopants, e.g., arsenic (As), phosphorous (P), etc., into them. In some embodiments, the first epitaxial structure 3032 can be coupled to each of the first nanostructures 3006 through a lightly doped region 3033 (e.g., SiGeB); and the second epitaxial structure 3034 can be coupled to each of the third nanostructures 3010 through a lightly doped region 3035 (e.g., SiP).

Corresponding to operation 2920 of FIG. 29, FIG. 39 is a cross-sectional view of the CFET structure 3000 including a first active gate structure 3042 and a second active gate structure 3044, at one of the various stages of fabrication. The cross-sectional view of FIG. 39 is cut along the lengthwise direction of an active region of the CFET structure 3000 (e.g., the X-direction illustrated above).

As shown, the first active gate structure 3042 wraps around each of the first nanostructures 3006; and the second active gate structure 3044 wraps around each of the third nanostructures 3010. To form the first active gate structure 3042 and second active gate structure 3044, the dummy gate structure 3002, and the remaining portions of the sacrificial oxide layers 3024 are removed. As such, a first gate trench, exposing each of the first nanostructures 3006, may be formed in the lower portion 3004-1 (e.g., the first level); and a second gate trench, exposing each of the third nanostructures 3010, may be formed in the upper portion 3004-2 (e.g., the second level). Next, the first active gate structure 3042 can be formed in the first gate trench to wrap around each of the first nanostructures 3006; and the second active gate structure 3044 can be formed in the second gate trench to wrap around each of the third nanostructures 3010.

In some embodiments, the first active gate structure 3042 can include a first gate dielectric and a first gate metal; and the second active gate structure 3044 can include a second gate dielectric and a second gate metal. The first/second gate dielectric may be formed of different high-k dielectric materials or a similar high-k dielectric material. Example high-k dielectric materials include a metal oxide or a silicate of Hf, Al, Zr, La, Mg, Ba, Ti, Pb, and combinations thereof. The first/second gate dielectric may include a stack of multiple high-k dielectric materials. The first gate metal may include one or more p-type work function metals, which may include TiN, TaN, Ru, Mo, Al, WN, ZrSi₂, MoSi₂, TaSi₂, NiSi₂, WN, other suitable p-type work function materials, or combinations thereof; and the second gate metal may include one or more n-type work function metals, may include Ti, Ag, TaAl, TaAlC, TiAlN, TaC, TaCN, TaSiN, Mn, Zr, other suitable n-type work function materials, or combinations thereof.

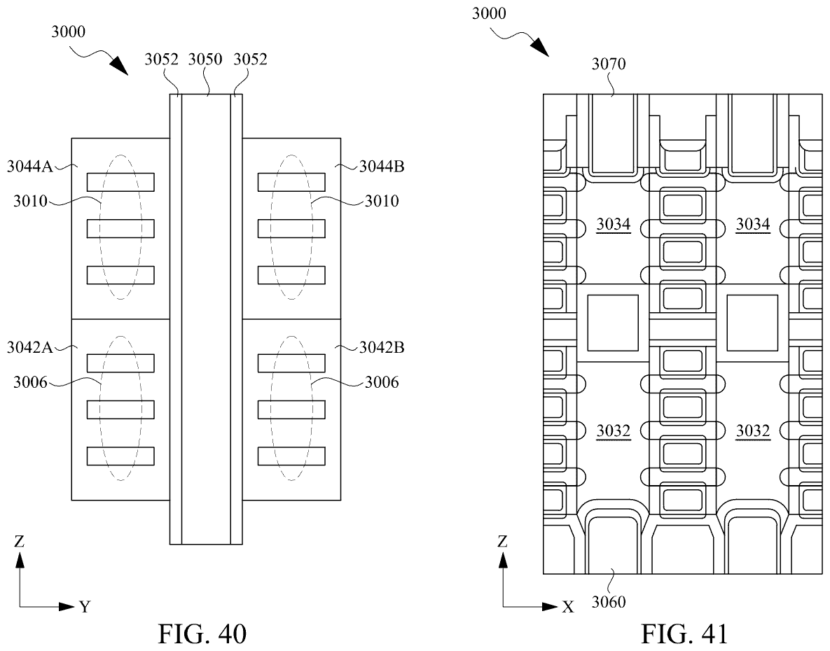

Corresponding to operation 2922 of FIG. 29, FIG. 40 is a cross-sectional view of the CFET structure 3000 including a power structure 3050, at one of the various stages of fabrication. The cross-sectional view of FIG. 40 is cut along the lengthwise direction of a gate structure of the CFET structure 3000 (e.g., the Y-direction illustrated above).

As shown, the power structure 3050 is configured to separate the first active gate structure 3042 into gate sections 3042A and 3042B, and separate the second active gate structure 3044 into gate sections 3044A and 3044B. The gate sections 3042A and 3042B are separated from each other along the Y-direction, and the gate sections 3044A and 3044B are separated from each other along the Y-direction. Further, the power structure 3050 is electrically isolated from the separated gate sections, e.g., gate sections 3042A and 3042B, gate sections 3044A and 3044B, with a dielectric structure 3052.

In some embodiments, the power structure 3050 can correspond to the wall structure 244/344, and the dielectric structure 3052 can correspond to the dielectric structure 242/342 (FIGS. 2-5). As such, the gate section 3042A and 3042B can correspond to the gate sections 230A and 230B or the gate sections 240A and 240B, respectively, and the gate section 3044A and 3044B can correspond to the gate sections 330A and 330B or the gate sections 340A and 340B, respectively. In some other embodiments, the power structure 3050 can correspond to the via structure 644A/744A or 644B/744B, and the dielectric structure 3052 can correspond to the dielectric structure 642/742 (FIGS. 6-9). As such, the gate section 3042A and 3042B can correspond to the gate sections 630A and 630B or the gate sections 640A and 640B, respectively, and the gate section 3044A and 3044B can correspond to the gate sections 730A and 730B or the gate sections 740A and 740B, respectively.

To form the power structure 3050, a middle portion of the first active gate structure 3042 and the second gate structure 3044, following a cut pattern discussed above (e.g., 242/342, 642/742), may be removed. For example, this middle portion of the first and second active gate structures is removed through at least one anisotropic etching process, thereby forming a vertical trench extending from the first level to the second level. Next, a dielectric material (e.g., silicon nitride) can be deposited to fill up the vertical trench, followed by deposition of a metal material (e.g., copper) to form the power structure 3050. The one-piece wall structure (e.g., 244/344) can be self-aligned with the vertical trench (i.e., no further lithography process). The duet of via structures (e.g., 644A/744A and 644B/744B) may be formed through another lithography process. For example, after the deposition of the dielectric material into the vertical trench, a lithography process can be performed to form a pair of vertical trenches extending through the dielectric material, followed by deposition of the metal material.

Upon the power structure 3050 being formed, at least two p-type transistors can be formed at the first level and on the opposite sides of the power structure 3050, respectively, and at least two n-type transistors can be formed at the second level and on the opposite sides of the power structure 3050, respectively. The p-type transistor can be operatively formed based on the first nanostructures 3006, the gate section 3042A or 3042B, and the pair of first epitaxial structures 3032. The n-type transistor can be operatively formed based on the third nanostructures 3010, the gate section 3044A or 3044B, and the pair of second epitaxial structures 3034.

Corresponding to operation 2924 of FIG. 29, FIG. 41 is a cross-sectional view of the CFET structure 3000 including first contact structures 3060 and second contact structures 3070, at one of the various stages of fabrication. The cross-sectional view of FIG. 41 is cut along the lengthwise direction of an active region of the CFET structure 3000 (e.g., the X-direction illustrated above).

As shown, the first contact structure 3060 is coupled to a corresponding one of the first epitaxial structures 3032; and the second contact structure 3070 is coupled to a corresponding one of the second epitaxial structures 3034. For example, the first contact structure 3060 may be formed below the first epitaxial structure 3032; and the second contact structure 3070 may be formed above the second epitaxial structure 3034. For another example, the first contact structure 3060 may wrap around the first epitaxial structure 3032; and the second contact structure 3070 may wrap around the second epitaxial structure 3034. In some embodiments, the first contact structure 3060 and the second contact structure 3070 may each be configured as an MD, as described above, which can include titanium, aluminum, nickel, tungsten, tantalum, or other suitable metal materials.

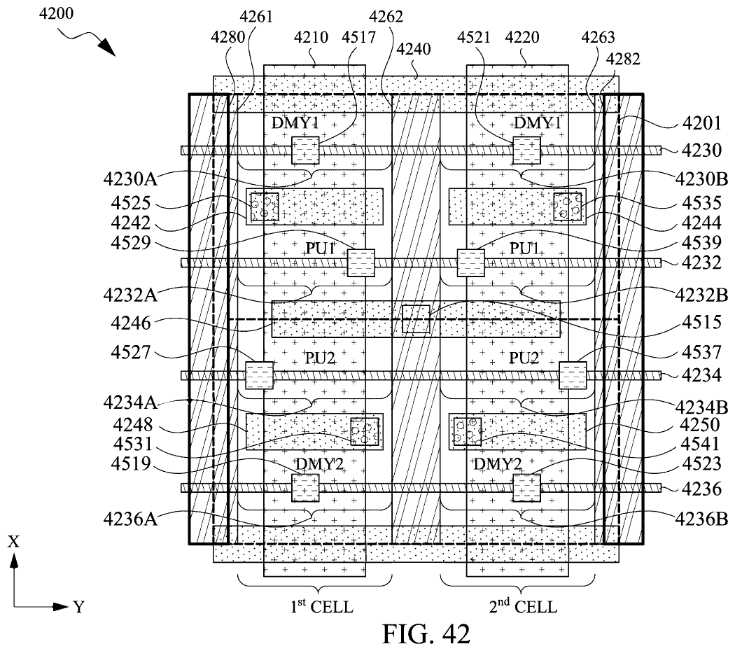

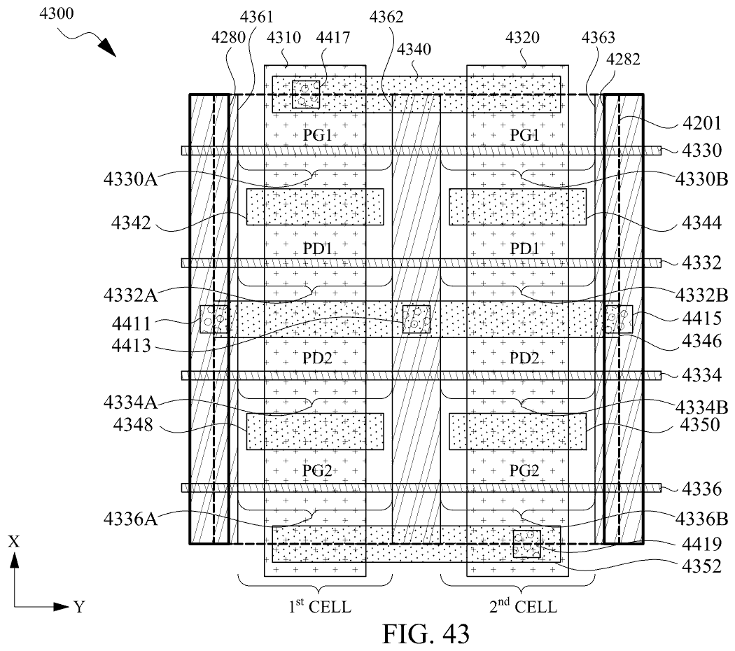

FIG. 42 and FIG. 43 respectively illustrate layouts 4200 and 4300 that can be collectively utilized to form a pair of the memory cells 100 (FIG. 1) configured in a CFET structure with an embedded power structure, in accordance with some embodiments. The CFET structure can include a number of first transistors disposed at a first level on the frontside of a substrate, and a number of second transistors disposed at a second, upper level on the frontside of the substrate. In some embodiments, each of these first and second transistors is configured as a GAA FET, with the first transistors and the second transistors having opposite conductive types. In some other embodiments, each of the first and second transistors can be formed as other type of transistor structures, while remaining within the scope of the present disclosure.

As depicted in FIGS. 42-43, each of the layouts 4200 and 4300 can include a cell boundary 4201 defining a physical area of the memory cell 100. The embedded power structure can be formed as a one-piece wall structure vertically extending from the first level to the second level. Further, when viewed from the top, such an embedded wall structure can be disposed along the cell boundary 201 of the memory cell 100. For example, the wall structure may laterally extend along one of the edges of the cell boundary 201, with the transistors all disposed on one (inner) side of that edge.

Generally, each of the layouts 4200 and 4300 can include a number of patterns configured for forming respective structures, and thus, such patterns of the disclosed layout are herein referred to as the structures to be formed, respectively, in the following discussion. For example, the layout 4200 includes patterns configured to form structures of the first transistors at the first level on the frontside; and the layout 4300 includes patterns configured to form structures of the second transistors at the second level on the frontside. Further, the layout 4200 includes patterns configured to form contact/via/interconnect structures disposed on a backside of the substrate (e.g., at a first level on the backside); and the layout 4300 includes patterns configured to form via/interconnect structures at a third level on the frontside (e.g., over the second level). It should be understood that each of the layouts 4200 and 4300 has been simplified for illustrative purposes, and thus, can include any of various other patterns while remaining within the scope of the present disclosure.

Referring first to FIG. 42, the layout 4200 can include patterns for forming active regions 4210 and 4220 and gate structures 4230, 4232, 4234 and 4236, respectively. The active regions 4210 and 4220 may extend in the X-direction; and the gate structures 4230 to 4236 may extend in the Y-direction. Each of the active regions 4210 and 4220 may be formed as a fin structure or a stack structure extending along the X-direction, and each of the gate structures 4230 to 4236 may be formed to extend in the Y-direction to traverse the active regions 4210 and 4220. The layout 4200 can further include a number of cut patterns, e.g., 4261, 4262, and 4263, each of which can extend along the X-direction traversing the gate structures 4230 to 4236. The cut patterns 4261 to 4263 can each be configured to form a dielectric structure, thereby dividing the gate structures 4230-4236 into separate gate sections. For example, the cut pattern 4261-4263 can divide the gate structures 4230, 4232, 4234, and 4236 into gate sections 4230A and 4230B, gate sections 4232A and 4232B, gate sections 4234A and 4234B, and gate sections 4236A and 4236B, respectively, as indicated in FIG. 42.

Referring next to FIG. 43, the layout 4300 can include patterns for forming active regions 4310 and 4320 and gate structures 4330, 4332, 4334 and 4336, respectively. The active regions 4310 and 4320 may extend in the X-direction; and the gate structures 4330 to 4336 may extend in the Y-direction. Each of the active regions 4310 and 4320 may be formed as a fin structure or a stack structure extending along the X-direction, and each of the gate structures 4330 to 4336 may be formed to extend in the Y-direction to traverse the active regions 4310 and 4320. The layout 4300 can further include a number of cut patterns, e.g., 4361, 4362, and 4363, each of which can extend along the X-direction traversing the gate structures 4330 to 4336. The cut patterns 4361 to 4363 can each be configured to form a dielectric structure, thereby dividing the gate structures 4330-4336 into separate gate sections. For example, the cut pattern 4361-4363 can divide the gate structures 4330, 4332, 4334, and 4336 into gate sections 4330A and 4330B, gate sections 4332A and 4332B, gate sections 4334A and 4334B, and gate sections 4336A and 4336B, respectively, as indicated in FIG. 43.

In some embodiments, the active regions 4210 and 4310 are vertically aligned with each other, the active regions 4220 and 4320 are vertically aligned with each other, the gate structures 4230 and 4330 are vertically aligned with each other, the gate structures 4232 and 4332 are vertically aligned with each other, the gate structures 4234 and 4334 are vertically aligned with each other, the gate structures 4236 and 4336 are vertically aligned with each other, the cut patterns 4261 and 4361 are vertically aligned with each other, the cut patterns 4262 and 4362 are vertically aligned with each other, and the cut patterns 4263 and 4363 are vertically aligned with each other. Further, the active regions 4210 and 4310 may be physically formed as a single structure (sometimes referred to as “active region 4210/4310”), the active regions 4220 and 4320 may be physically formed as a single structure (sometimes referred to as “active region 4220/4320”), the gate structures 4230 and 4330 may be physically formed as a single structure (sometimes referred to as “gate structure 4230/4330”), the gate structures 4232 and 4332 may be physically formed as a single structure (sometimes referred to as “gate structure 4232/4332”), the gate structures 4234 and 4334 may be physically formed as a single structure (sometimes referred to as “gate structure 4234/4334”), and the gate structures 4236 and 4336 may be physically formed as a single structure (sometimes referred to as “gate structure 4236/4336”).

Based on the manufacturing processes described in FIGS. 18-41, the layouts 4200 and 4300 can be collectively utilized to form a number of first transistors at a first level on the frontside of a substrate and a number of second transistor at a second, upper level on the frontside, in which the first transistors are operatively formed based on a plural number of first nanosheets and a plural number of first epitaxial structures, and the second transistors are operatively formed based on a plural number of second nanosheets and a plural number of second epitaxial structures.

For example, the transistors PU1 and PU2 of a first memory cell 100 and the transistors PU1 and PU2 of a second memory cell 100 can be formed at the first level based on the layout 4200 (as indicated in FIG. 42), and the transistors PD1, PD2, PG1, and PG2 of the first memory cell 100 and the transistors PD1, PD2, PG1, and PG2 of the second memory cell 100 can be formed at the second level based on the layout 4300 (as indicated in FIG. 43). Further, a first dummy transistor DMY1 and a second dummy transistor DMY2 of each of the first and second memory cells 100 can be formed based on the layout 4200 (FIG. 42). In some embodiments, the transistors PU1 and PU2 (including DMY1 and DMY2) of the first and second memory cells 100 at the first level can be formed with the p-type conductivity, and the transistors PD1, PD2, PG1, and PG2 of the first and second memory cells 100 at the second level can be formed with the n-type conductivity.

As a representative example, in FIG. 42, the transistor PU1 of the first memory cell 100 (e.g., between the cut patterns 4261 and 4262) can include its channel, gate terminal, and source/drain terminals formed by a subset of the first nanosheets in the active region 4210, the gate section 4232A, and a subset of the first epitaxial structures formed from the active region 4210 and disposed on opposite sides of the gate structure 4232, respectively. The transistor PU2 of the first memory cell 100 can include its channel, gate terminal, and source/drain terminals formed by another subset of the first nanosheets in the active region 4210, the gate section 4234A, and another subset of the first epitaxial structures formed from the active region 4210 and disposed on opposite sides of the gate structure 4234, respectively. The transistor DMY1 of the first memory cell 100 can include its channel, gate terminal, and source/drain terminals formed by yet another subset of the first nanosheets in the active region 4210, the gate section 4230A, and yet another subset of the first epitaxial structures formed from the active region 4210 and disposed on opposite sides of the gate structure 4230, respectively. The transistor DMY2 of the first memory cell 100 can include its channel, gate terminal, and source/drain terminals formed by yet another subset of the first nanosheets in the active region 4210, the gate section 4236A, and yet another subset of the first epitaxial structures formed from the active region 4210 and disposed on opposite sides of the gate structure 4236, respectively.

As another representative example, in FIG. 43, the transistor PD1 of the first memory cell 100 (e.g., between the cut patterns 4361 and 4362) can include its channel, gate terminal, and source/drain terminals formed by a subset of the second nanosheets in the active region 4310, the gate section 4332A, and a subset of the second epitaxial structures formed from the active region 4310 and disposed on opposite sides of the gate structure 4332, respectively. The transistor PG1 of the first memory cell 100 can include its channel, gate terminal, and source/drain terminals formed by another subset of the second nanosheets in the active region 4310, the gate section 4330A, and another subset of the second epitaxial structures formed from the active region 4310 and disposed on opposite sides of the gate structure 4330, respectively. The transistor PD2 of the first memory cell 100 can include its channel, gate terminal, and source/drain terminals formed by yet another subset of the second nanosheets in the active region 4310, the gate section 4334A, and yet another subset of the second epitaxial structures formed from the active region 4310 and disposed on opposite sides of the gate structure 4334, respectively. The transistor PG2 of the first memory cell 100 can include its channel, gate terminal, and source/drain terminals formed by yet another subset of the second nanosheets in the active region 4310, the gate section 4336A, and yet another subset of the second epitaxial structures formed from the active region 4310 and disposed on opposite sides of the gate structure 4336, respectively.

Referring again to FIG. 42, the layout 4200 can further include patterns for forming source/drain contact structures (MDs) 4240, 4242, 4244, 4246, 4248, 4250, and 4252, respectively. Similarly in FIG. 43, the layout 4300 can further include patterns for forming source/drain contact structures (MDs) 4340, 4342, 4344, 4346, 4348, 4350, and 4352, respectively. Each of these MDs is configured to electrically connect to the source/drain terminal of a corresponding transistor.

For example, in FIG. 42, the MD 4240 is connected to a first source/drain terminal of the transistor DMY1 of the first memory cell 100 and a first source/drain terminal of the transistor DMY1 of the second memory cell 100; the MD 4242 is connected to a second source/drain terminal of the transistor DMY1 and a first source/drain terminal of the transistor PU1 of the first memory cell 100; the MD 4244 is connected to a second source/drain terminal of the transistor DMY1 and a first source/drain terminal of the transistor PU1 of the second memory cell 100; the MD 4246 is connected to a second source/drain terminal of the transistor PU1 and a first source/drain terminal of the transistor PU2 of the first memory cell 100, and a second source/drain terminal of the transistor PU1 and a first source/drain terminal of the transistor PU2 of the second memory cell 100; the MD 4248 is connected to a second source/drain terminal of the transistor PU2 and a first source/drain terminal of the transistor DMY2 of the first memory cell 100; the MD 4250 is connected to a second source/drain terminal of the transistor PU2 and a first source/drain terminal of the transistor DMY2 of the second memory cell 100; and the MD 4252 is connected to a second source/drain terminal of the transistor DMY2 of the first memory cell 100 and a second source/drain terminal of the transistor DMY2 of the second memory cell 100.

In FIG. 43, the MD 4340 is connected to a first source/drain terminal of the transistor PG1 of the first memory cell 100 and a first source/drain terminal of the transistor PG1 of the second memory cell 100; the MD 4342 is connected to a second source/drain terminal of the transistor PG1 and a first source/drain terminal of the transistor PD1 of the first memory cell 100; the MD 4344 is connected to a second source/drain terminal of the transistor PG1 and a first source/drain terminal of the transistor PD1 of the second memory cell 100; the MD 4346 is connected to a second source/drain terminal of the transistor PD1 and a first source/drain terminal of the transistor PD2 of the first memory cell 100, and a second source/drain terminal of the transistor PD1 and a first source/drain terminal of the transistor PD2 of the second memory cell 100; the MD 4348 is connected to a second source/drain terminal of the transistor PD2 and a first source/drain terminal of the transistor PG2 of the first memory cell 100; the MD 4350 is connected to a second source/drain terminal of the transistor PD2 and a first source/drain terminal of the transistor PG2 of the second memory cell 100; and the MD 4352 is connected to a second source/drain terminal of the transistor PG2 of the first memory cell 100 and a second source/drain terminal of the transistor PG2 of the second memory cell 100.

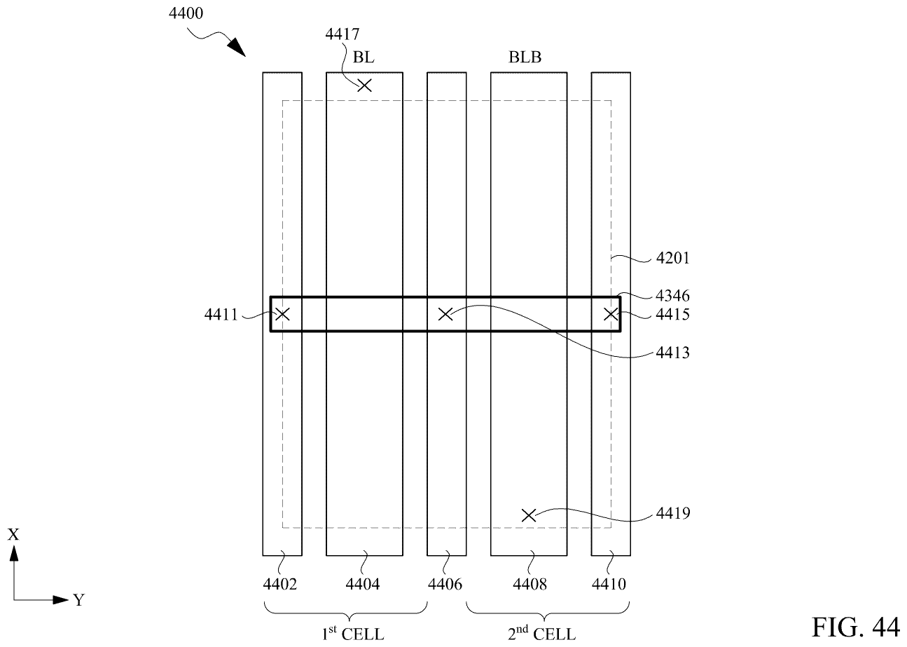

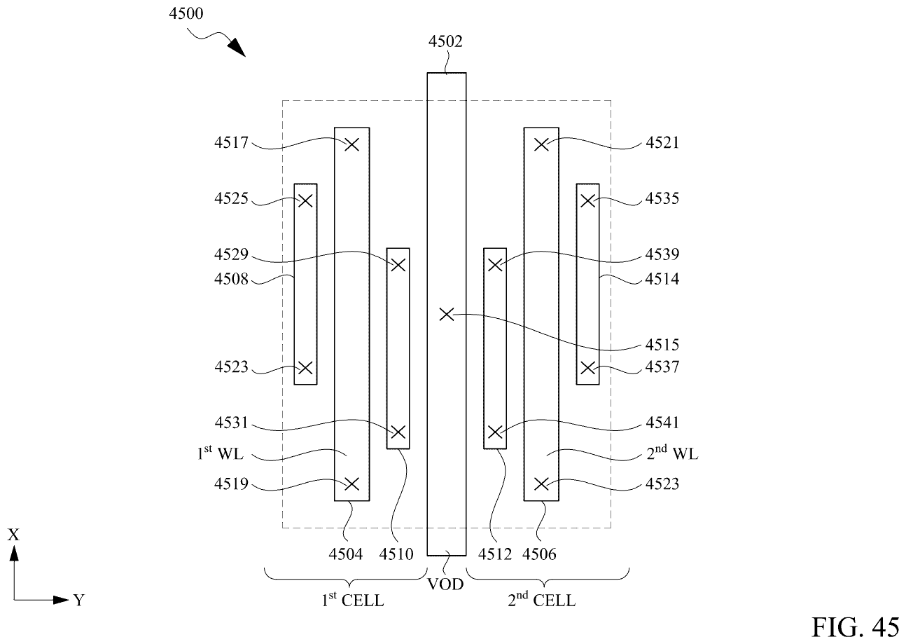

In some embodiments, the layouts 4200 and 4300 each include a pair of patterns for forming power structures 4280 and 4282, respectively. The power structure 4280 can extend along one of the edges of the cell boundary 4201 in the X-direction, and the power structure 4282 can extend along the other one of the edges of the cell boundary 4201 in the X-direction. The power structures 4282 and 4282 can vertically extend through the first and second levels, and be configured to carry the ground voltage VSS. For example, the power structures 4280 and 4282 can be formed below (coupled to) the MD 4346 at the second level, downwardly extends to the first level, and be formed above (coupled to) the MDs 4240 and 4252. As will be shown below in FIGS. 44-45, a number of M0 tracks, formed above the second frontside level, can be configured to carry the ground voltage VSS. As such, the ground voltage VSS can be carried “within” a cell boundary, or without an additional tap cell.

FIG. 44 illustrates a layout 4400 that can be utilized to form a number of frontside metal tracks disposed over the first and second memory cells 100 (shown in FIGS. 42-43) and FIG. 45 illustrates a layout 4500 that can be utilized to form a number of backside metal tracks disposed below the first and second memory cells 100 (shown in FIGS. 42-43), in accordance with some embodiments. It should be understood that the layouts of FIGS. 44 and 45 are provided simply for illustrative purposes, and are not intended to limit the scope of the present disclosure.

The layout 4400 refers to an arrangement of plural M0 tracks, 4402, 4404, 4406, 4408, and 4410, with respect to the cell boundary 4201, where the M0 tracks 4402, 4406, and 4410 are collectively configured to carry the ground voltage VSS for the first and second memory cells 100, the M0 track 4404 is configured as a BL for the first and second memory cells 100, and the M0 track 4408 is configured as a BLB for the first and second memory cells 100. In some embodiments, these M0 tracks can extend along the X-direction. The M0 tracks 4402, 4406, and 4410 can be coupled to the MD 4436 through VDs 4411, 4413, and 4415 (which are also shown in FIG. 43), respectively; and the M0 track 4402 can be coupled to the MD 4340 through VD 4417 (which is also shown in FIG. 43); and the M0 track 4408 can be coupled to the MD 4352 through VD 4419 (which is also shown in FIG. 43).

The layout 4500 refers to an arrangement of plural BM0 tracks, 4502, 4504, 4506, 4508, 4510, 4512, and 4514, with respect to the cell boundary 4201, where the BM0 tracks 4502 is configured to carry the supply voltage VDD for the first and second memory cells 100, the BM0 track 4504 is configured as a WL for the first memory cell 100, the BM0 track 4506 is configured as a WL for the second memory cell 100, the BM0 tracks 4508-4510 are configured as internal contact structures for the first memory cell 100, and the BM0 tracks 4512-4514 are configured as internal contact structures for the second memory cell 100. In some embodiments, these BM0 tracks can extend along the X-direction. The BM0 track 4502 can be coupled to the MD 4246 through BVD 4515 (which is also shown in FIG. 42); the BM0 track 4504 can be coupled to the gate sections 4230A and 4236A through BVGs 4517 and 4519 (which are also shown in FIG. 42), respectively; and the BM0 track 4506 can be coupled to the gate sections 4230B and 4236B through BVGs 4521 and 4523 (which are also shown in FIG. 42), respectively. The BM0 track 4508 can be coupled to the MD 4242 and the gate section 4234A through BVD 4525 and BVG 4527 (which are also shown in FIG. 42), respectively; the BM0 track 4510 can be coupled to the MD 4248 and the gate section 4232A through BVD 4531 and BVG 4529 (which are also shown in FIG. 42), respectively; the BM0 track 4514 can be coupled to the MD 4244 and the gate section 4234B through BVD 4535 and BVG 4537 (which are also shown in FIG. 42), respectively; and the BM0 track 4512 can be coupled to the MD 4520 and the gate section 4232B through BVD 4541 and BVG 4539 (which are also shown in FIG. 42), respectively.

In one aspect of the present disclosure, a device is disclosed. The device includes a substrate having a first side and a second side opposite to each other; a first transistor and a second transistor in a first level on the first side of the substrate, the first and second transistors having a first conductivity; a third transistor, a fourth transistor, a fifth transistor, and a sixth transistor in a second level on the first side of the substrate and over the first level, the third to sixth transistors having a second conductivity; a first interconnect structure, a second interconnect structure, a third interconnect structure, and a fourth interconnect structure formed on the second side of the substrate, wherein the first and second interconnect structures are each configured to carry a supply voltage, and the third and fourth interconnect structures are each configured to carry a ground voltage; and a power structure vertically extending through the first and second levels, and configured to electrically couple a source/drain terminal of the third transistor and a source/drain terminal of the fourth transistor to the third interconnect structure and the fourth interconnect structure, respectively. When viewed from the top, the power structure is interposed between the fifth transistor and the fourth transistor along a first lateral direction, and between the third transistor and the sixth transistor along the first lateral direction.

In another aspect of the present disclosure, a semiconductor device is disclosed. The semiconductor device includes a first active region formed at a first level on a first side of a substrate and extending along a first lateral direction; a second active region formed at the first level and extending along the first lateral direction; a first gate structure formed at the first level, extending in a second lateral direction, and traversing the first and second active regions; a second gate structure formed at the first level, extending in the second lateral direction, and traversing the first and second active regions; a third active region formed at a second level over the first level on the first side, extending in the first lateral direction, and vertically above and aligned with the first active region; a fourth active region formed at the second level, extending in the first lateral direction, and vertically above and aligned with the second active region; a third gate structure formed at the second level, extending in the second lateral direction, and vertically above and aligned with the third active region; a fourth gate structure formed at the second level, extending in the second lateral direction, and vertically above and aligned with the fourth active region; and a power structure vertically extending from the first level to the second level, interposed between the first active region and the second active region along the second lateral direction, and interposed between the third active region and the fourth active region along the second lateral direction. The first active region and the second gate structure operatively form a first transistor of a memory cell that has a first conductivity, the second active region and the first gate structure operatively form a second transistor of the memory cell that has the first conductivity, the third active region and the third gate structure operatively form a third transistor of the memory cell that have a second conductivity, the third active region and the fourth gate structure operatively form a fourth transistor of the memory cell that have the second conductivity, the fourth active region and the third gate structure operatively form a fifth transistor of the memory cell that have the second conductivity, and the fourth active region and the fourth gate structure operatively form a sixth transistor of the memory cell that have the second conductivity.

In yet another aspect of the present disclosure, a method for forming a memory device is disclosed. The method includes forming, at a first level on a first side of a substrate, a first active region extending along a first lateral direction; forming, at the first level, a second active region extending along the first lateral direction; forming, at the first level, a first gate structure extending along a second lateral direction and traversing the first and second active regions; forming, at the first level, a second gate structure extending along the second lateral direction and traversing the first and second active regions; forming, at a second level over the first level on the first side, a third active region extending in the first lateral direction; forming, at the second level, a fourth active region extending along the first lateral direction; forming, at the second level, a third gate structure extending along the second lateral direction; forming, at the second level, a fourth gate structure extending along the second lateral direction; and forming a power structure vertically extending from the first level to the second level, interposed between the first active region and the second active region along the second lateral direction, and interposed between the third active region and the fourth active region along the second lateral direction. The first active region and the second gate structure operatively form a first transistor of a memory cell that has a first conductivity, the second active region and the first gate structure operatively form a second transistor of the memory cell that has the first conductivity, the third active region and the third gate structure operatively form a third transistor of the memory cell that have a second conductivity, the third active region and the fourth gate structure operatively form a fourth transistor of the memory cell that have the second conductivity, the fourth active region and the third gate structure operatively form a fifth transistor of the memory cell that have the second conductivity, and the fourth active region and the fourth gate structure operatively form a sixth transistor of the memory cell that have the second conductivity.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device, comprising:
a substrate having a first side and a second side opposite to each other;
a first transistor and a second transistor in a first level on the first side of the substrate, the first and second transistors having a first conductivity;
a third transistor, a fourth transistor, a fifth transistor, and a sixth transistor in a second level on the first side of the substrate and over the first level, the third to sixth transistors having a second conductivity;
a first interconnect structure, a second interconnect structure, a third interconnect structure, and a fourth interconnect structure formed on the second side of the substrate, wherein the first and second interconnect structures are each configured to carry a supply voltage, and the third and fourth interconnect structures are each configured to carry a ground voltage; and
a power structure vertically extending through the first and second levels, and configured to electrically couple a source/drain terminal of the third transistor and a source/drain terminal of the fourth transistor to the third interconnect structure and the fourth interconnect structure, respectively;
wherein, when viewed from a top of the device, the power structure is interposed between the fifth transistor and the fourth transistor along a first lateral direction, and between the third transistor and the sixth transistor along the first lateral direction.

2. The device of claim 1, further comprising:
a first dummy transistor disposed next to the first transistor along a second lateral direction perpendicular to the first lateral direction, and having a source/drain terminal replaced with a first isolation structure; and
a second dummy transistor disposed next to the second transistor along the second lateral direction, and having a source/drain terminal replaced with a second isolation structure.

3. The device of claim 2, wherein the first dummy transistor and second dummy transistor are each formed with the first conductivity.

4. The device of claim 2, further comprising:
a first contact structure electrically connected to the source/drain terminal of the third transistor;
a second contact structure electrically connected to the source/drain terminal of the fourth transistor;
a third contact structure vertically disposed below the first isolation structure, and electrically connected to the third interconnect structure; and
a fourth contact structure vertically disposed below the second isolation structure, and electrically connected to the fourth interconnect structure.

5. The device of claim 4, wherein the power structure is formed as a one-piece wall structure, the one-piece wall structure being configured to connect the first and second contact structures to the third and fourth contact structures.

6. The device of claim 4, wherein the power structure is formed as a first via structure and a second via structure, the first via structure being configured to connect the first contact structure to the third contact structure, and the second via structure being configured to connect the second contact structure to the fourth contact structure.

7. The device of claim 1, wherein each of the first to fourth interconnect structures extends along a second lateral direction perpendicular to the first lateral direction.

8. The device of claim 7, wherein the first interconnect structure and the third interconnect structure are aligned along the second lateral direction, and the second interconnect structure and the fourth interconnect structure are aligned along the second lateral direction.

9. The device of claim 7, wherein the first interconnect structure and the third interconnect structure are disposed opposite the first transistor from the power structure along the first lateral direction, and the second interconnect structure and the fourth interconnect structure are disposed opposite the second transistor from the power structure along the first lateral direction.

10. The device of claim 1, wherein the first to sixth transistors operatively form a Static Random Access Memory (SRAM) cell.

11. A semiconductor device, comprising:
a first active region formed at a first level on a first side of a substrate and extending along a first lateral direction;
a second active region formed at the first level and extending along the first lateral direction;
a first gate structure formed at the first level, extending in a second lateral direction, and traversing the first and second active regions;
a second gate structure formed at the first level, extending in the second lateral direction, and traversing the first and second active regions;
a third active region formed at a second level over the first level on the first side, extending in the first lateral direction, and vertically above and aligned with the first active region;
a fourth active region formed at the second level, extending in the first lateral direction, and vertically above and aligned with the second active region;
a third gate structure formed at the second level, extending in the second lateral direction, and vertically above and aligned with the third active region;
a fourth gate structure formed at the second level, extending in the second lateral direction, and vertically above and aligned with the fourth active region; and
a power structure vertically extending from the first level to the second level, interposed between the first active region and the second active region along the second lateral direction, and interposed between the third active region and the fourth active region along the second lateral direction;
wherein the first active region and the second gate structure operatively form a first transistor of a memory cell that has a first conductivity, the second active region and the first gate structure operatively form a second transistor of the memory cell that has the first conductivity, the third active region and the third gate structure operatively form a third transistor of the memory cell that have a second conductivity, the third active region and the fourth gate structure operatively form a fourth transistor of the memory cell that have the second conductivity, the fourth active region and the third gate structure operatively form a fifth transistor of the memory cell that have the second conductivity, and the fourth active region and the fourth gate structure operatively form a sixth transistor of the memory cell that have the second conductivity.

12. The semiconductor device of claim 11, wherein the memory cell is a Static Random Access Memory (SRAM) cell.

13. The semiconductor device of claim 11, wherein
the first active region and the first gate structure operatively form a first dummy first transistor that has a source/drain terminal replaced with a first isolation structure; and
the second active region and the second gate structure operatively form a second dummy first transistor that has a source/drain terminal replaced with a second isolation structure.

14. The semiconductor device of claim 13, further comprising:
a first contact structure having at least a portion vertically disposed over and electrically connected to a source/drain terminal of the fourth transistor;
a second contact structure having at least a portion vertically disposed over and electrically connected to a source/drain terminal of the fifth transistor;
a third contact structure vertically disposed below the first isolation structure; and
a fourth contact structure vertically disposed below the second isolation structure.

15. The semiconductor device of claim 14, further comprising:
a first interconnect structure formed on a second side of the substrate, extending along the first lateral direction, and configured to carry a ground voltage, the third contact structure being coupled to the first interconnect structure; and
a second interconnect structure formed on the second side of the substrate, extending along the first lateral direction, and configured to carry the ground voltage, the fourth contact structure being coupled to the second interconnect structure.

16. The semiconductor device of claim 15, wherein the power structure is formed as a one-piece wall structure, the one-piece wall structure being configured to connect the first and second contact structures to the third and fourth contact structures.

17. The semiconductor device of claim 15, wherein the power structure is formed as a first via structure and a second via structure, the first via structure being configured to connect the first contact structure to the third contact structure, and the second via structure being configured to connect the second contact structure to the fourth contact structure.

18. A method for forming a memory device, comprising:
forming, at a first level on a first side of a substrate, a first active region extending along a first lateral direction;
forming, at the first level, a second active region extending along the first lateral direction;
forming, at the first level, a first gate structure extending along a second lateral direction and traversing the first and second active regions;
forming, at the first level, a second gate structure extending along the second lateral direction and traversing the first and second active regions;
forming, at a second level over the first level on the first side, a third active region extending in the first lateral direction;
forming, at the second level, a fourth active region extending along the first lateral direction;
forming, at the second level, a third gate structure extending along the second lateral direction;
forming, at the second level, a fourth gate structure extending along the second lateral direction; and
forming a power structure vertically extending from the first level to the second level, interposed between the first active region and the second active region along the second lateral direction, and interposed between the third active region and the fourth active region along the second lateral direction;
wherein the first active region and the second gate structure operatively form a first transistor of a memory cell that has a first conductivity, the second active region and the first gate structure operatively form a second transistor of the memory cell that has the first conductivity, the third active region and the third gate structure operatively form a third transistor of the memory cell that have a second conductivity, the third active region and the fourth gate structure operatively form a fourth transistor of the memory cell that have the second conductivity, the fourth active region and the third gate structure operatively form a fifth transistor of the memory cell that have the second conductivity, and the fourth active region and the fourth gate structure operatively form a sixth transistor of the memory cell that have the second conductivity.

19. The method of claim 18, further comprising:
forming, on a second side of the substrate, a first interconnect structure configured to carry a ground voltage; and
forming, on the second side of the substrate, a second interconnect structure configured to carry the ground voltage;
wherein the power structure is configured to electrically couple respective source/drain terminals of the fourth and fifth transistors to the ground voltage.

20. The method of claim 18, wherein the power structure is formed as a one-piece wall structure or a pair of via structures.
